(19) United States
(12) Patent Application Publication
(10) Pub. No.: US 2021/0308755 A1
(43) Pub. Date: Oct. 7, 2021

(54) Core-Shell Particles and Composite Material Synthesized Therefrom

(71) Applicant: Persimmon Technologies Corporation, Wakefield, MA (US)

(72) Inventors: Ankur Gupta, Wakefield, MA (US); Brett Guralnick, Wakefield, MA (US); Jayaraman Krishnasamy, Boxborough, MA (US)

(21) Appl. No.: 17/221,021

(22) Filed: Apr. 2, 2021

Related U.S. Application Data
(60) Provisional application No. 63/004,177, filed on Apr. 2, 2020.

(51) Int. Cl. B22F 1/02; H01F 1/147

(52) U.S. Cl. CPC B22F 1/02; H01F 1/147; B22F 2302/25; B22F 2302/20; B22F 2302/30; B22F 2301/052

(57) ABSTRACT

A system for producing a soft magnetic material having a core-shell structure includes a gas supply configured to supply at least one gas; and a furnace configured to receive the at least one gas. A flow of the at least one gas is configured to be varied to provide a shell on a particle in the furnace.

### CROSS REFERENCE TO RELATED APPLICATION

This application claims priority under 35 USC 119(e) to U.S. Provisional Application No. 63/004,177, filed Apr. 2, 2020, the content of which is hereby incorporated by reference in its entirety.

### BACKGROUND

### Technical Field

The example and non-limiting embodiments disclosed herein relate generally to soft magnetic materials and, more particularly, to materials having and produced from core-shell powder particles in which a soft magnetic core is surrounded by an electrically isolating layer.

Brief Description of Prior Developments

Soft magnetic materials for use in forming soft-magnetic composite (SMC) materials include ferrous materials that can be magnetized but do not tend to stay magnetized. Magnetically “hard” materials generally stay magnetized. Soft magnetic materials generally have lower coercivities than hard magnetic materials.

### SUMMARY

In accordance with one aspect, a system for producing a soft magnetic material having a core-shell structure comprises a gas supply configured to supply at least one gas; and a furnace configured to receive the at least one gas. A flow of the at least one gas is configured to be varied to provide a shell on a particle in the furnace.

In accordance with another aspect, a method of providing a soft magnetic material having a core-shell structure comprises purging a furnace with nitrogen (or other inert gases like argon or a vacuum environment); heating the furnace; determining if a shell on a ferrous particle in the furnace is to be an oxide, a nitride, or an oxynitride; and oxidizing and/or nitriding the ferrous particle.

In accordance with another aspect, a soft magnetic material comprises a soft magnetic core; and a shell surrounding the soft magnetic core, the shell being chemically bonded to the core. The soft magnetic core comprises a soft magnetic elemental metal or alloy. The shell comprises an electrically insulating material.

In accordance with another aspect, a reactor comprises a cylindrical portion configured to be heated and comprising an inner wall and rotatable about an axis extending longitudinally through the cylindrical portion, the cylindrical portion having a first open end and a second opposing open end and having at least one vane extending from the inner wall; a first narrow portion attached to the first open end; and a second narrow portion attached to the second opposing open end.

In accordance with another aspect, a method of producing a soft magnetic composite material comprises providing a powder comprising at least one of iron, cobalt, nickel, aluminum, silicon, or gadolinium; forming shells on particles of the powder, the shells comprising an oxide, a nitride, or an oxynitride to form particles of a soft magnetic material having a core-shell structure; and forming a solid soft magnetic composite material using the particles of the soft magnetic material having the core-shell structure.

In accordance with another aspect, a method of producing a soft magnetic composite material comprises providing a powder comprising at least one of iron, cobalt, nickel, aluminum, silicon, or gadolinium; forming shells on particles of the powder, the shells comprising a nitride or an oxynitride to form particles of a soft magnetic material having a core-shell structure; and depositing the particles of the soft magnetic material having the core-shell structure to form a solid soft magnetic composite material.

In accordance with another aspect, a system for producing a soft magnetic powder material of particles having core-shell structures comprises a source of iron or iron alloy particles; a source of at least one gas comprising at least one of nitrogen and oxygen; a flow controller configured to control a flow of the at least one gas to the source of iron or iron alloy particles; and a heater configured to heat the at least one gas at the source of iron or iron alloy particles. A flow of the at least one gas is configured to be varied to provide a shell of at least one of a nitride, an oxide, or an oxynitride on the iron or iron alloy particles.

In accordance with another aspect, a soft magnetic material comprises a powder comprising particles of at least iron or iron alloy; and shells on the particles of the powder, the shells comprising nitride or an oxynitride to form particles of a soft magnetic material having a core-shell structure.

In accordance with another aspect, a soft magnetic composite material comprises a plurality of particles of a soft magnetic material, the particles each having a core-shell structure. A core of each particle comprises a ferrous material that forms a ferromagnetic domain, and a shell on each core comprises a nitride material that forms an insulating boundary between adjacent cores.

In accordance with another aspect, a soft magnetic material comprises a powder comprising particles of at least iron or iron alloy; and shells on the particles of the powder, the shells comprising nickel oxide to form particles of a soft magnetic material having a core-shell structure.

In accordance with another aspect, a soft magnetic composite material comprises a plurality of particles of a ferrous soft magnetic material, the ferrous soft magnetic material forming ferromagnetic domains, and a shell on each core comprising nickel oxide, the shells forming insulating boundaries between adjacent ferromagnetic domains.

In accordance with another aspect, an apparatus comprises a combustion chamber having a gas inlet configured to receive a gas, a fuel inlet configured to receive a fuel, a particle inlet, and an outlet; and a stage configured to receive a stream of particles propelled from the outlet of the combustion chamber.

### BRIEF DESCRIPTION OF THE DRAWINGS

The foregoing aspects and other features are explained in the following description, taken in connection with the accompanying drawings, wherein:

FIG. 1 is a schematic diagram illustrating a heat treatment process enabling growth of an insulation layer around an individual particle of a powder;

FIG. 2 is a flow diagram showing a process for producing a soft magnetic material for use in a soft magnetic composite material;

FIG. 3a is a graphical representation of a time-temperature profile and gas flow rate for a pre-heat treatment stage followed by an oxidation phase in a process for producing a soft magnetic material;

FIG. 3b is a graphical representation of a time-temperature profile and gas flow rate for a pre-heat and homogenization stages followed by a nitriding phase in a process for producing a soft magnetic material;

FIG. 3c is a graphical representation of an alternate time-temperature plot in which an initial homogenization stage is eliminated;

FIGS. 3d and 3e are scanning electron micrograph (SEM) images of cross-sectional views of cores and shells illustrating variations in shell thicknesses due to heat treatment duration;

FIGS. 4a-4c are schematic representations of a reaction chamber design;

FIG. 5 is a graphical representation of a time-temperature plot of a heat treatment process on soft magnetic composite material produced from powder with a core-shell structure;

FIG. 6 is a schematic representation of one example powder particle produced by processes described herein;

FIG. 7 is a sample SEM image of a particle with an outer shell;

FIGS. 8a and 8b are graphical representations showing X-ray diffraction results of particles with core-shell structures (nitride based and oxide based);

FIG. 9 is a graphical and SEM representation of auger electron spectroscopy analysis on an individual particle showing variations of percentages of iron, aluminum, and oxygen versus sputtering (or etch) time;

FIGS. 10a and 10b are representations of scanning electron microscopy/energy dispersive spectroscopy (SEM/EDS) images and analysis results, respectively, showing variations of iron, aluminum, silicon, and oxygen between particle core and particle boundaries, the analysis being carried out on soft magnetic composite material;

FIGS. 11a and 11b are representations of TEM/EDS images and analysis, respectively, showing particle boundary elemental concentration variation between particle core and particle boundaries, the analysis being carried out on soft magnetic composite material;

FIGS. 12a-12c illustrate X-ray photoelectron spectroscopy (XPS) analysis of a powder surface;

FIGS. 13a-13c illustrate XPS analysis of a powder surface showing aluminum, oxygen, and nitrogen peaks corresponding to aluminum oxides and aluminum nitrides;

FIGS. 14a-14c illustrate a XPS analysis of oxide and nitride shell powder surface;

FIG. 15 is a graphical representation of hysteresis loss shown as loss versus excitation frequency in which a reduction in hysteresis loss due to heat treatment of soft magnetic composite material produced with particles of core-shell structure is shown;

FIG. 16a illustrates particles after coating with nickel at various magnifications, cross-sectional views of a single particle showing core and a thickness of nickel coating, and XPS analyses of nickel coated particles with a variation of elemental concentration versus etch time;

FIG. 16b is a graphical representation of variations of elemental concentration versus etch time for oxidized nickel coated particles;

FIG. 16c is a graphical representation of a time-temperature plot to produce nickel oxide shell on particles pre-coated with nickel; and

FIG. 17 is a schematic block diagram showing the primary components of one embodiment of the system and method for making a material having domains with insulated boundaries.

### DETAILED DESCRIPTION OF EMBODIMENTS

Soft magnetic composite material may be produced by spray-deposition of powder particles of core-shell structure. One example embodiment of forming soft magnetic material for use as SMC material may involve the use of a powder in which the powder is pre-processed so each individual powder particle has a soft magnetic core enclosed in an insulating shell. One example of a core-shell composition may be one where the core is comprised predominantly or solely of soft magnetic elements such as iron, cobalt, nickel, and gadolinium and the shell is composed mainly of crystalline oxides and nitrides which are good electrical insulators. The example embodiments disclosed herein describe example processes to produce powder particles with this core-shell morphology. As used herein, the term “powder” refers to a collection of finely divided granular particles that have a general ability to flow.

The example embodiments described herein enable production of powder with a core-shell structure with the following properties:
A particle forming the core comprises iron, although other elements may be present;
The insulating shell is comprised primarily of one or more crystalline phases of oxides, nitrides, and oxynitrides. An alternate carbide shell may be produced by changing source gases (precursors);
The shell is devoid or substantially devoid of iron oxides. Iron oxides are generally undesirable and detrimental to magnetic properties;
The shell is chemically bonded to the core;
The thickness of the shell is substantially uniform and substantially continuous around the cores;
To achieve the above characteristics of the shell, aluminum may be added as an alloying element to the core. For desirable magnetic properties, aluminum in the core may not be desirable and may need to be minimized. Aluminum in the core may be between 0.0 wt. % to 7.0 wt. % (up to about 7.0 wt. %). In some examples, there may not be any aluminum, or there may be trace amounts of aluminum. In some alternate embodiments, aluminum content may be about 3.5 wt. %. Creation of a shell with the desired properties, while keeping concentrations of aluminum at or below 3.5 wt. % in the core, are described herein;
For desirable magnetic properties, silicon in the core may be used up to about 3 wt. %. The processes described herein do not alter the silicon content in the core.

The raw material for the process may be powder produced as an alloy with iron as its primary element and small amounts of aluminum or other elements serving as the oxidizing or nitriding metal. The process of producing the desired core-shell morphology generally involves heat treatment of the raw powder in a controlled environment.

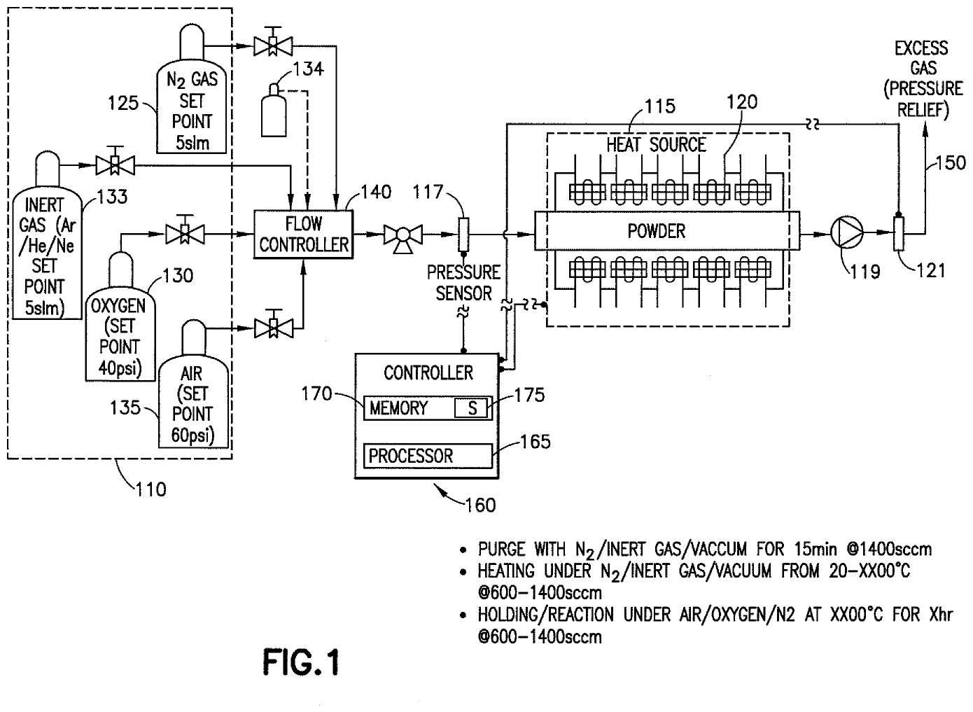

FIG. 1 shows a schematic of the heat treatment process. The heat treatment process is designed to enable growth of the insulation layer around individual particles of the powder. Heat treatment increases the diffusion rate of the oxidizing elements from the particle core to the surface as well as oxidation and nitriding reactions at the particle surface. The powder may be constantly tumbled during the heat treatment process to maximize powder surface exposed to the reacting environment.

Referring to FIG. 1, one exemplary embodiment of a system for producing particles having core-shell structures is shown generally at 100 and is hereinafter referred to as “system 100.” System 100 uses a powder heat treatment setup as shown, the setup comprising a gas supply 110 and a powder treatment phase which is carried out in a furnace 115 or reactor comprising one or more heaters 120. The setup may comprise other means for gas supply and powder treatment. The gas supply 110 comprises one or more gas sources such as a nitrogen source 125 (for example, diatomic nitrogen), an oxygen source 130 (for example, diatomic oxygen), an air source 135, or another inert gas (for example, argon, neon, or helium, sources of which are shown at 133) which are fed to a flow controller 140. The nitrogen, oxygen, and/or air are fed through the flow controller 140 to the powder in the furnace 115. Pressure of the gas(es) fed to the furnace 115 may be monitored using a pressure sensor 117, which may be in communication with at least one controller 160. A vacuum pump 119 may be located downstream of the furnace 115. An oxygen sensor 121 may be located downstream of the vacuum pump 119 and may be in communication with the controller 160. Pressure from excess nitrogen, oxygen, air, and/or other gases may be relieved from the furnace 115 through a suitable vent 150.

The gas sources used are not limited to nitrogen, argon, helium, oxygen, and air, however, as other gases such as ammonia and hydrazine may be used as sources (for example, shown at 134) of nitrogen, and hydrogen peroxide, ozone, and ozone-enriched air may be used as sources of oxygen. Ammonia and hydrazine, for example, break down during reaction to produce elemental nitrogen that reacts to form the shell, and hydrogen peroxide, ozone, and ozone-enriched air, for example, break down during reaction to produce elemental oxygen that reacts to form the shell.

The flow controller 140, the pressure sensor 117, and the furnace 115 may be connected to the controller 160 comprising at least one processor 165 and at least one memory 170 comprising software 175 to control operations of the system 100. Operation of the system 100 using the controller 160 may allow for adjustment and control of the gases and heat based at least on a pressure sensed at the pressure sensor 117, temperature in the furnace 115, and temperatures and flow rates of the gases. Other operations of the system 100 may be possible.

Either open loop control or closed loop control may be used in the system 100. If the system 100 is used with open-loop control, the temperature of the furnace 115 depends on the input from the controller 160 and is not fed back to the controller 160 for further consideration in forming the particles having the core-shell structures. If the system 100 is used with closed-loop control, the temperature of the furnace 115 may be fed back to the controller 160 for control of one or both of pressure and power to the heaters 120 in order to adjust the properties of the particles.

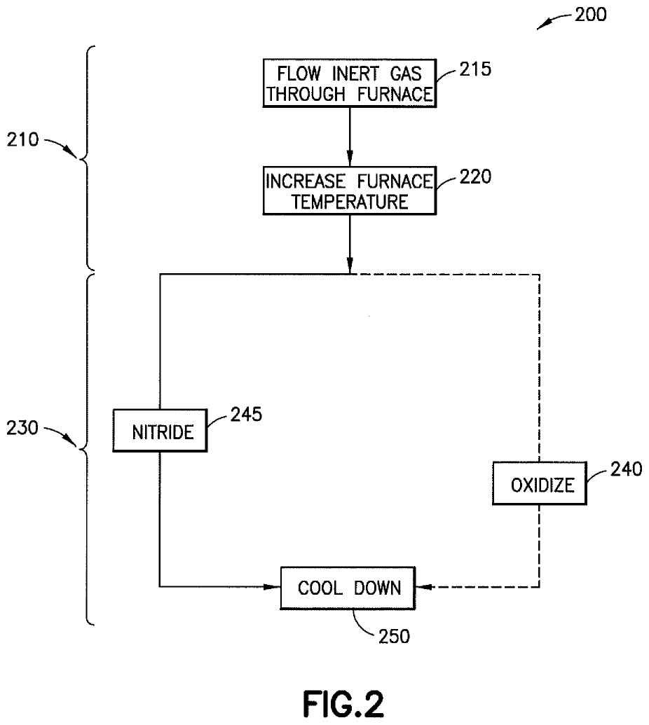

Referring to FIG. 2, one example of a process for producing soft magnetic material is shown generally at 200 and is hereinafter referred to as “process 200.” Process 200 involves two stages: (1) a pre-heat treatment stage 210 and (2) a stage 230 in which either an oxidation or nitriding is carried out (nitriding/oxidizing stage 230).

The pre-heat treatment stage 210 may be carried out in an inert or near-inert environment which may be accomplished by flowing nitrogen (or other inert gas) through a furnace at a steady rate (purge step 215). The flow is maintained as the furnace temperature is ramped up to the desired temperature (heating step 220). The temperature is maintained at levels low enough that nitrogen (or other inert gas) does not react with the elements in the alloyed particle. Depending upon whether the soft magnetic material is to have a nitride coating or an oxide coating, the nitriding/oxidizing stage 230 is carried out. Additional stages such as homogenization stages may be introduced as desired.

Homogenization may be carried out to eliminate or mitigate any chemical and structural irregularities from solid-state material and to obtain a more uniform chemical composition, lattice structure, and properties. One example homogenization process involves heating material to an elevated temperature and holding for the desired amount of time. The homogenization process can be carried out in multiple cycles. In some examples, a homogenization step may involve more than one cycle where material is heated and cooled down several times for the desirable effects. An example of a multi-step homogenization process is melting and rapid casting of alloys to remove segregation of dendrites, alloying elements, and inclusions. Similarly, cast products can be homogenized by heating to elevated temperatures and holding for specific times over multiple cycles. In the current example processes described herein, the material is heated to 800° C. and held for 180 minutes and cooled down to allow the chemical composition to achieve uniformity. The material is then cooled to 300° C. for atomic rearrangement. The material is then heated to the nitriding or oxidation reaction temperature.

If the desired shell composition is an oxide, oxidation of the surface of the particles is accomplished by providing oxygen (or air or other oxygen-containing gas) at a set temperature and then oxidizing in an oxidizing step 240. If the desired shell composition is a nitride, nitriding is accomplished by maintaining nitrogen flow in a nitriding step 245, but raising the temperature to a level that facilitates the nitriding reaction.

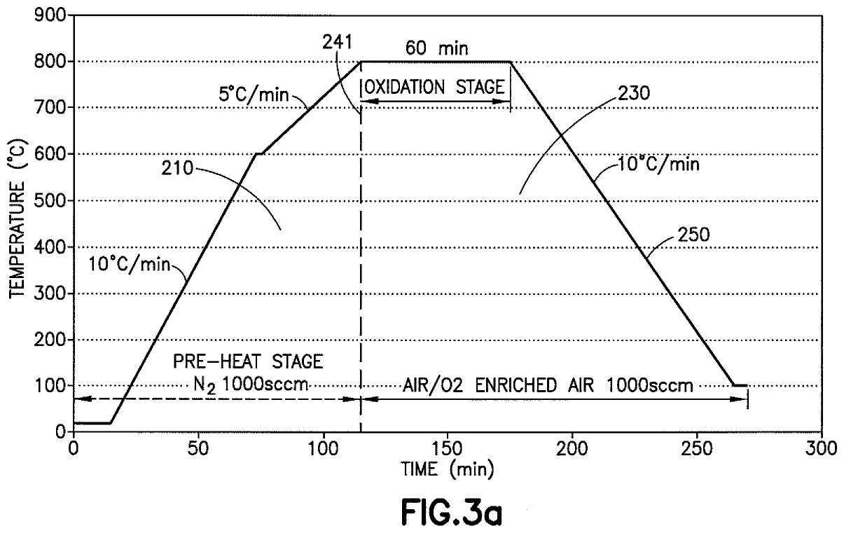

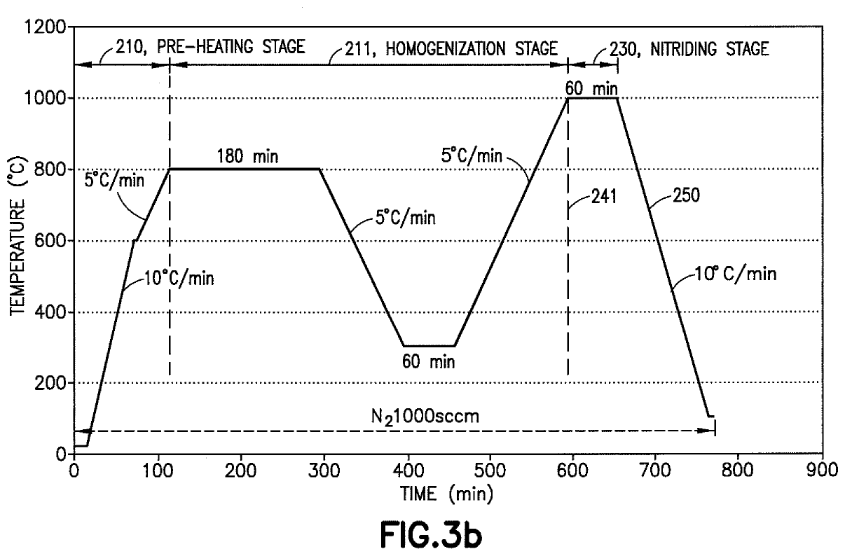

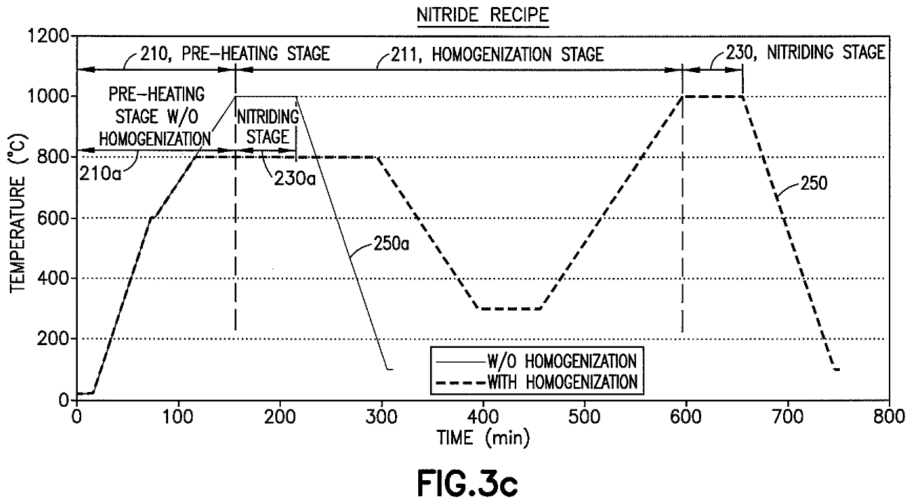

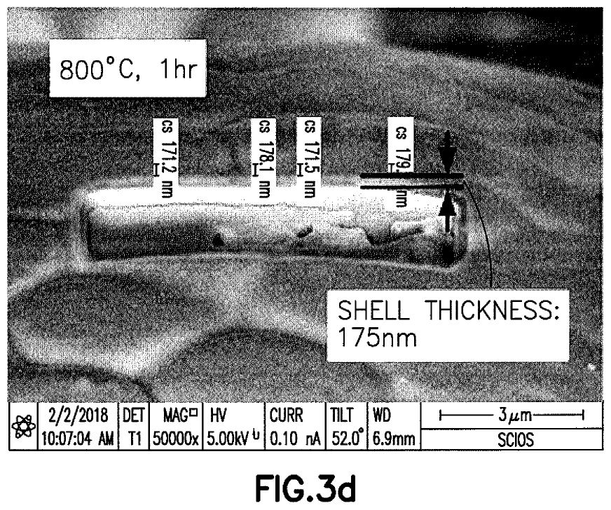

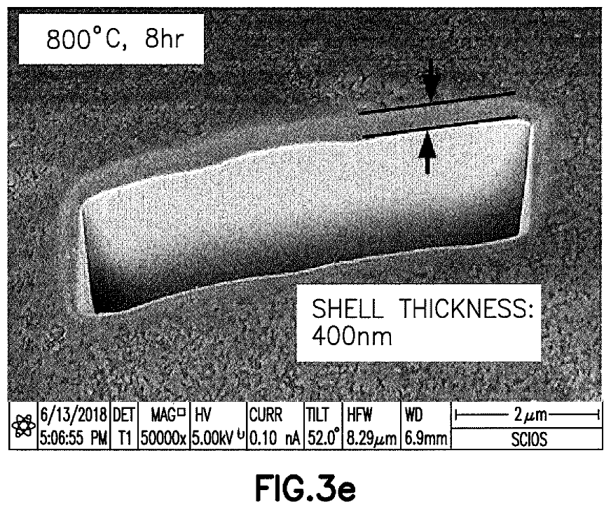

Referring now to FIGS. 3a and 3b, FIG. 3a shows a time-temperature profile and gas flow rate for the pre-heat treatment stage 210 followed by the oxidation phase. FIG. 3b shows a time-temperature profile and gas flow rate for the pre-heat treatment stage 210 and a homogenization stage 211 followed by the nitriding phase 230. In the pre-heat treatment stage 210, temperature is ramped up (possibly at a faster or slower rate than shown). In the homogenization stage 211, the elevated temperature is maintained for a prolonged period. Note that during the transition (shown at 241) from pre-heat phase to oxidation phase, nitrogen flow transitions to oxygen (air or other) flow.

Referring back to FIG. 2, whether the oxidation is carried out in the oxidizing step 240 or the nitriding phase is carried out in the nitriding step 245, a controlled cool down step 250 is carried out. The gas flow rate and gas source may remain unchanged.

Referring back to FIGS. 3a and 3b, additional process details and variations may be incorporated into the process 200. For example, an alternate inert media (for example, argon) or vacuum may be used during a pre-heat stage such as at the pre-heat treatment stage 210. The heat treatment time-temperature plot shown in FIG. 3b involves pre-heating, homogenization, and nitriding. Any meta-stable phase formed during the powder production process is converted to a more stable phase during the pre-heat stage, which happens in a nitrogen (or nitrogen-rich) environment. In the alternative, the pre-heat stage may be carried out in a relatively inert argon (or argon-rich) environment. The nitrogen is introduced during the nitriding stage. Argon or vacuum can also be reintroduced during the cooling stage. Using argon or vacuum in place of nitrogen in the pre-heat stage enables limiting and controlling the exposure time of the powder to nitrogen. The efficacy of using argon as the inert media has been verified experimentally.

In one step nitriding, an alternate to the nitriding time-temperature plot shown in FIG. 3a is shown at 210a in FIG. 3c, where the homogenization stage is eliminated. FIG. 3c compares the pre-heating stage without homogenization (at 210a) at 800° C. with the pre-heating stage 210 at 1000° C. between 0 and 150 minutes. After pre-heating without homogenization (at 210a), a nitriding phase 230a is carried out, followed by a cool down step 250a. The efficacy of pre-heating without homogenization has been verified experimentally.

In the heat treatment, the thickness of the shell can be controlled by varying the duration of time that the powder is held at the maximum temperature. As shown in FIGS. 3d and 3e, shell thickness variation may be due to the duration of the heat treatment. Thicker shells require longer heat treatment durations. For one particular alloy composition, a thickness of 150 nm was achieved after 1 hour of heat treatment and a thickness of 400 nm was achieved after 8 hours of heat treatment. A shell thickness of 150 nm has been adequate to produce soft magnetic composite material with the desired magnetic properties. As shown in FIG. 3d, increasing the time of the heat treatment may produce a thickness of 175 nm. As an alternative to increasing the time, variation in shell thickness may be achieved by changing the maximum temperature at which powder is held.

With regard to heat treatment temperature, FIG. 3b shows the temperature of heat treatment to be 1000° C. Depending on the alloy composition, this temperature may vary from 700 to 1100° C.

With regard to the heat treatment ramp rate of the powder, a preferred temperature ramp rate for the reaction is 5° C./min at the high temperature (600-1100° C.) range and 10° C./min at the elevated temperature (100-600° C.) range. Similar ramp rates may also be applied during the cooling phase. Other ramp rates higher and lower (2-20° C./min) than those specified above can be applied depending on the construction material of the reaction chamber/tube and heating methods. Quartz tube is one example of a preferred material because its low coefficient of thermal expansion renders it less susceptible to thermal shocks. The ramp rate of 5° C./min is optimal for aluminum oxide chamber/tubes because of its poor thermal shock resistance.

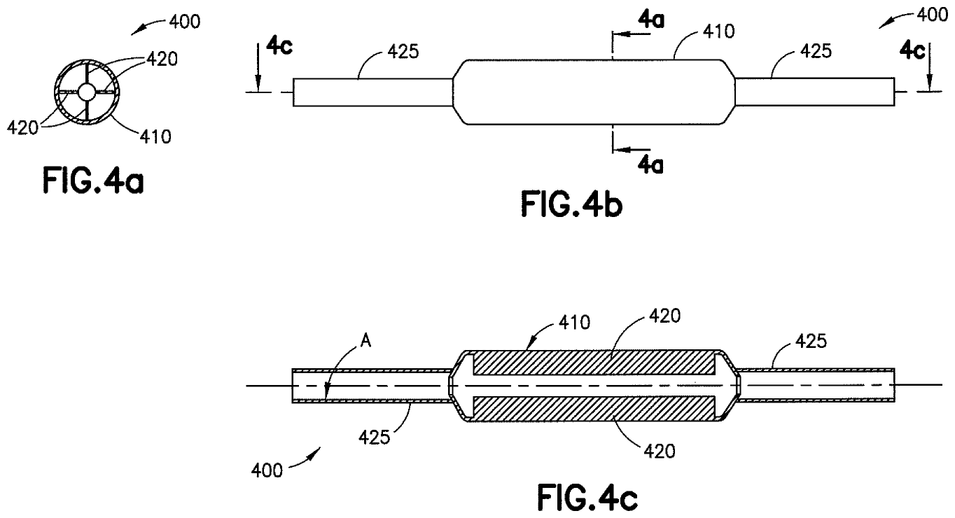

Referring now to FIGS. 4a-4c, one example of a custom reaction chamber/tube used for producing heat treatment (HT) powder using processes described above is shown generally at 400. In one example, the geometry of reactor or tube 400 is such that a wider mid-section has two narrow sections extending therefrom. The tube 400 has a cylindrical section 410 which holds the powder. This cylindrical section 410 also contains vanes 420 (four vanes located at 90° from each other are shown in FIGS. 4a and 4c, although any number of vanes can be used) extending inward from an inner wall of the cylindrical section 410. As the tube 400 rotates about an axis A extending through the cylindrical section 410 (FIG. 4c), these vanes 420 lift the powder, exposing it to the reactive gases present in the tube 400. The vanes 420 then drop the powder. This method assures a good mixing of powder throughout the process and an equal probability of reaction at the powder surface, which promotes a growth of shell layer of substantially the same thickness on every particle. Two narrow end sections 425 are sealed to prevent any infiltration of oxygen and other gases from the surrounding atmosphere into the tube 400. The desired inert atmosphere and precursor (in the form of gas) is introduced into the tube 400 from one end section 425 and exits from the other, thus maintaining unidirectional flow. The construction material for the tube 400 can be quartz, aluminum oxide, nickel-based alloys and super alloys, and Cobalt-based alloys and super alloys. Nickel-based super alloys and Cobalt-based super alloys are families of alloys capable of maintaining strength and corrosion resistance at high temperatures for extended period. Some examples of such alloys include, but are not limited to, HAYNES® 282®, Alloy 800H/HT®, and the like. These materials maintain their strength at high temperature (for example, when the tube 400 is heated) and are non-reactive to the alloy powder and precursor gases. The tube 400 may be tumbled/rotated at about 9 or 10 revolutions per minute (RPM) for a uniform mixing of powder. However, in other example embodiments, the tube 400 may be tumbled or rotated at less than or greater than 9 or 10 RPM as desired.

Regarding gas flow through the reaction chamber defined by the tube 400, prior to the pre-heat stage, the tube 400 may be flushed or voided of any oxygen. One approach is carried out by the flowing of inert gas (nitrogen/argon) through the tube 400 at a rate of about 1000-1400 sccm (standard cubic centimeters per minute) for at least 15 minutes. During the pre-heat and homogenization stage(s), this nitrogen or argon based environment is maintained through a steady flow of nitrogen or argon gas through the process chamber or tube 400. A gas flow rate of about 1000-1400 sccm is maintained during the entire period of the process irrespective of the stage and gas, although other flow rates less than or greater than 1000-1400 sccm may be desirable. Oxygen concentration inside the tube 400 is maintained at less than about 500 ppm (parts per million). The pressure inside the tube 400 is maintained at about 1.5-2 psig (pounds per square inch gauge). A gas relief valve (for example, vent 150) may be used to help maintain the pressure in the desired range. Alternatively, the pressure in the chamber may be controlled by others means such as pressure sensor, control valve, and programmable logic controller. The chamber pressure, oxygen concentration, tumbling speed, gas flow rates, and chamber temperature are continuously monitored during the process.

Though the described example methods were developed for the specific purpose of producing soft-magnetic composite materials through spray forming, they can also be applied to a broader range of powders. Described below are extensions to the range of applicability of the methods. The term “raw alloy” powder is used to refer to powder prior to processing, and the term “processed” powder is used to refer to powder after the processing. The term “spray-forming” refers to formation of a soft magnetic composite material or non-magnetic composite material by propelling particles at high temperature onto a flat surface. Upon impact the particles deform and adhere to the surface. The composite material may be referred to as “bulk.”

With regard to particle shapes and sizes, even though the example methods were developed with spherical shaped gas-atomized powder particles, the methods are applicable to powder particles with non-spherical, angular, or irregular shapes as well as particles produced through other processes such as water-atomization. Even though the described example method was used in particle size range of 25-100 microns, it can also be used in particles beyond this size range for applications other than spray-forming that may require those sizes.

The methods described herein can also be used in powders with elemental metals such as aluminum, nickel, chromium, vanadium, molybdenum, rare-earth elements, and the like on the surface. Various wet chemistry and solid-state deposition methods can be employed to deposit a thin layer of metal. Such methods include, but are not limited to, atomic layer deposition (ALD), physical vapor deposition (PVD), chemical vapor deposition (CVD), thermal evaporation, electroless deposition, electro pulse deposition (EPD), etc.

The example embodiments described herein may also be extended to other alloying elements, for example, particles having non-ferrous cores. Powder compositions involving iron alloyed with titanium or silicon can produce shells comprising the respective nitrides or oxynitrides.

The particles forming the powder with core-shell structure described herein can be used to produce bulk materials through processes other than spray-forming. Examples of such processes include, but are not limited to, powder metallurgical processes such as compaction, sintering, spark-plasma sintering, flash-sintering, hot-isostatic pressing, and the like. Cladding processes such as laser cladding may also be used. Examples of spray-forming processes that can be utilized for producing bulk materials include, but are not limited to, high-velocity oxy-fuel (HVOF), high-velocity air-fuel (HVAF), hybrid HVOF-HVAF processes, atmospheric and vacuum plasma spray (APS/VPS), cold spray, arc spray, and the like.

The efficacy of the example processes described herein may be affected by the aluminum content. For example, with regard to the aluminum content, the described example method employs aluminum to be available as the reactant metal for the oxidation or nitriding reaction. The oxide based shells have been produced for particles with greater than or equal to about 7 wt. % aluminum in the core. Nitride based shells have been produced for powders with greater than or equal to about 3.5 wt. % aluminum in the core.

Referring to FIG. 5, the results of heat treatment of soft magnetic composite material produced by spray-forming the powder with a core-shell structure is shown. Materials produced by spray forming powders with a core-shell morphology are characterized by high internal stress, strain, and dislocations. Since internal strain increases material hysteresis loss and reduces magnetic permeability, it is desirable to release the strain through a post-heat treatment of the spray formed material. The heat treatment process may be optimized to reduce internal strain, and at the same time, minimize inter-particle diffusion across the insulating shell.

FIG. 5 shows a time-temperature plot of this post-heat treatment process at 600. The soft magnetic composite material is heated to a specific temperature and maintained at that temperature for predetermined time (for example, between 200 minutes to 800 minutes) under an inert atmosphere. During holding steps (shown at 610), the material goes through several processes (recovery, recrystallization, and grain growth). During these steps 610, dislocation present in the material annihilates (dislocation density decreases) and the material releases the internal strains (shifts towards equilibrium state). When the dislocation annihilation completes, grain starts to grow at the expense of the smaller grains and grain boundaries. This is the point where hysteresis losses are the lowest in the material. Besides the dislocation annihilation in the materials, the retained austenite (y; non-magnetic/paramagnetic) is also converted into the ferrite (a; ferromagnetic), if any.

The HT temperature and time is specific to each material depending on its alloy composition and mechanical properties. The HT temperature is close to the alloy's curie temperature (Ta). The heat treatment time is determined from the degree of deformation (dislocation density).

Besides the reduction in hysteresis and overall losses, saturation flux and permeability of the material also increase upon the HT of material.

The following HT conditions provide the lowest hysteresis loss. An inert atmosphere may be used for post HT of spray formed materials. The inert atmosphere can be nitrogen, argon, or a mixture of the two gases. As an alternative, post HT may be carried out in a vacuum.

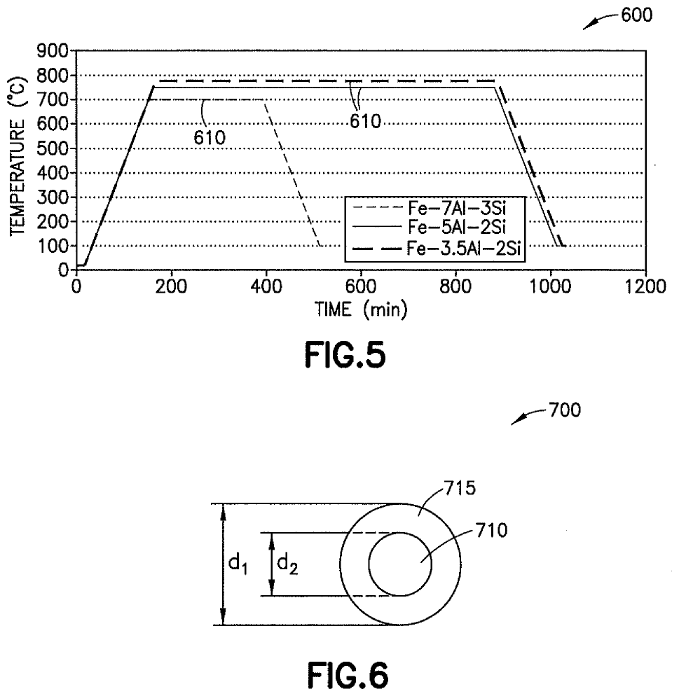

Referring now to FIG. 6, one example powder particle having a core-shell structure and for use in forming a soft magnetic composite material is shown at 700. Example powders may be produced in which particle sizes d₁ range from 25 to 100 microns. Prior to processing, cores 710 of the powder particles may have an alloy composition of aluminum: 3.5 wt. %-9 wt. %, silicon: 1 wt. %-3 wt. %, and the remainder being iron. Lesser amounts of aluminum are preferred (for example, less than about 4.0 wt. % in order to maintain suitable levels of insulation). The precise composition and thickness of an insulating shell 715 depends upon the alloy composition of the particles as well as the heat treatment settings. Depending on the material used for the shell, the particle of the material 700 may be used to form a soft magnetic composite material comprising soft magnetic domains separated by nitride based or oxide based insulation boundaries. Using SEM/FIB techniques, it has been confirmed that the shell 715 may have a thickness range (d₂) of 0.05 to 0.50 microns. The average thickness d₂ can be controlled through heat treatment settings, such as temperature, duration, gas flow, and atmospheric composition of the gas flow. XPS/AES measurements confirm that the shell 715 has less than 1 atom % iron. Through XRD and TEM analyses, the shell 715 has been confirmed to be composed of crystalline phases of alumina, spinel, aluminum nitrides, and oxynitrides. Alpha and gamma crystalline phases of alumina and phases of spinel comprise the shell produced from the oxidation process. A combination of aluminum nitrides, oxynitrides, and oxides may comprise the shell 715 produced by the nitriding process. Pure oxides and nitrides of Fe may be below detectable levels in the shell 715. Batches of processed powder up to 10 pounds (lbs.) in weight have been successfully produced. Processed powder resulting from the invention has been successfully spray formed to produce bulk material with low eddy losses. Soft magnetic composite material was produced through two types of spray forming processes, namely, HVAF and HVOF. Soft magnetic composite material may be produced by alternative processes including, but not limited to, hybrid HVOF-HVAF, APS, VPS, cold spray, arc spray, sintering, laser cladding, and the like.

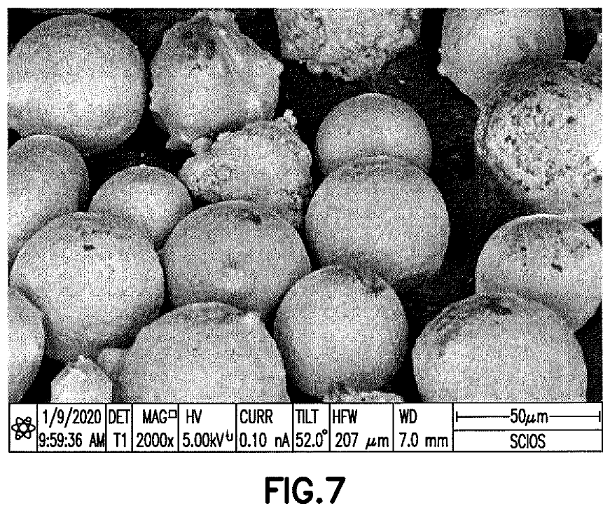

Referring now to FIG. 7, a sample SEM image of particles 700 with outer shells is shown. The particles 700 may comprise about 5 wt % aluminum, 2 wt % silicon, and iron powder. The particles 700 shown are gas atomized and about 45-65 microns in diameter and spherical in shape.

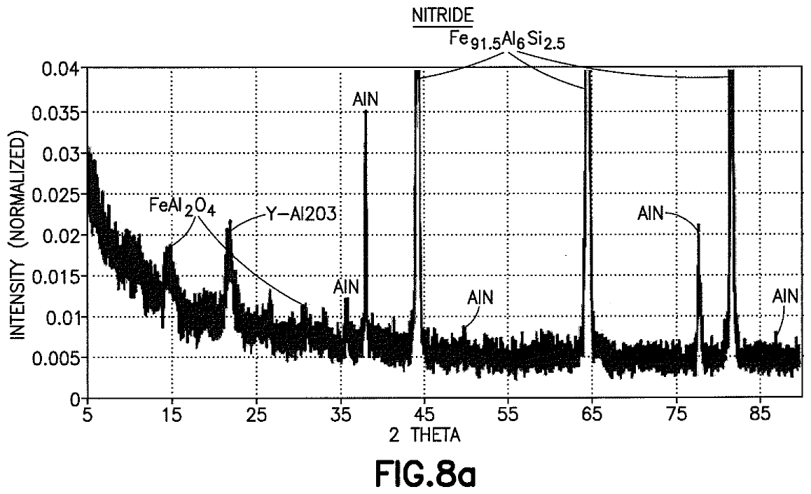

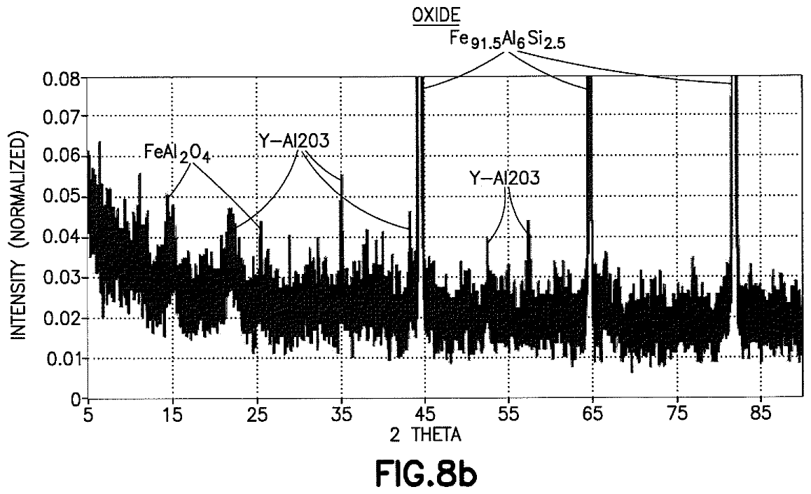

Referring now to FIG. 8a, X-ray diffraction of powders produced through the oxidation process shows peaks corresponding to a desirable gamma phase of aluminum oxide as well as a spinel (FeAl₂O₄) phase. No peaks corresponding to undesirable iron oxides are present.

Referring now to FIG. 8b, X-ray diffraction of powders (individual particles) produced through the nitriding process shows peaks corresponding to a gamma phase of aluminum oxide and aluminum nitride as well as a spinal (FeAl₂O₄) phase. No peaks corresponding to iron oxides are present.

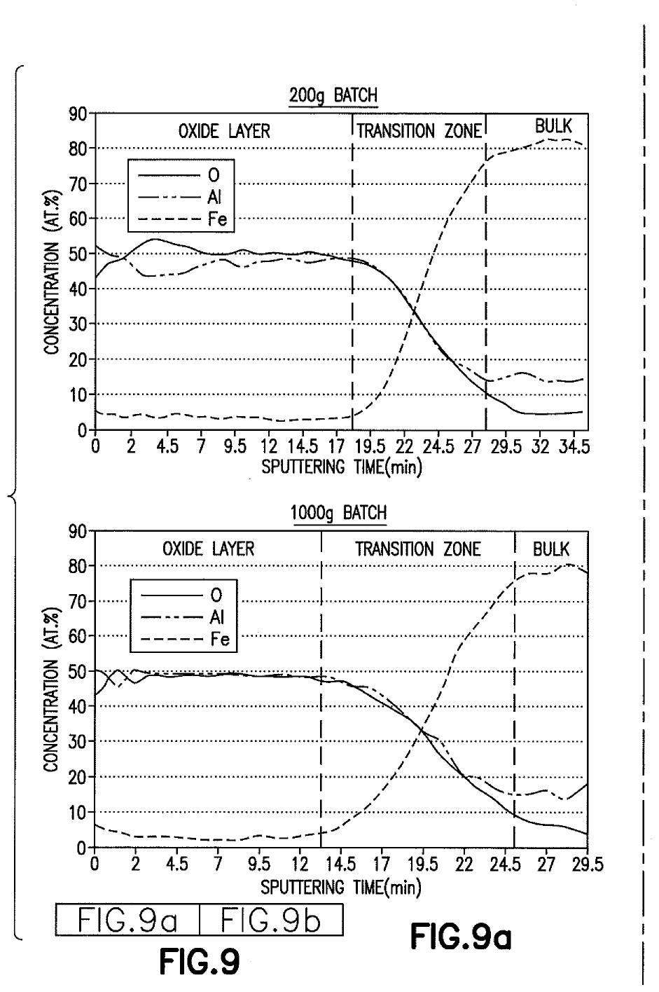

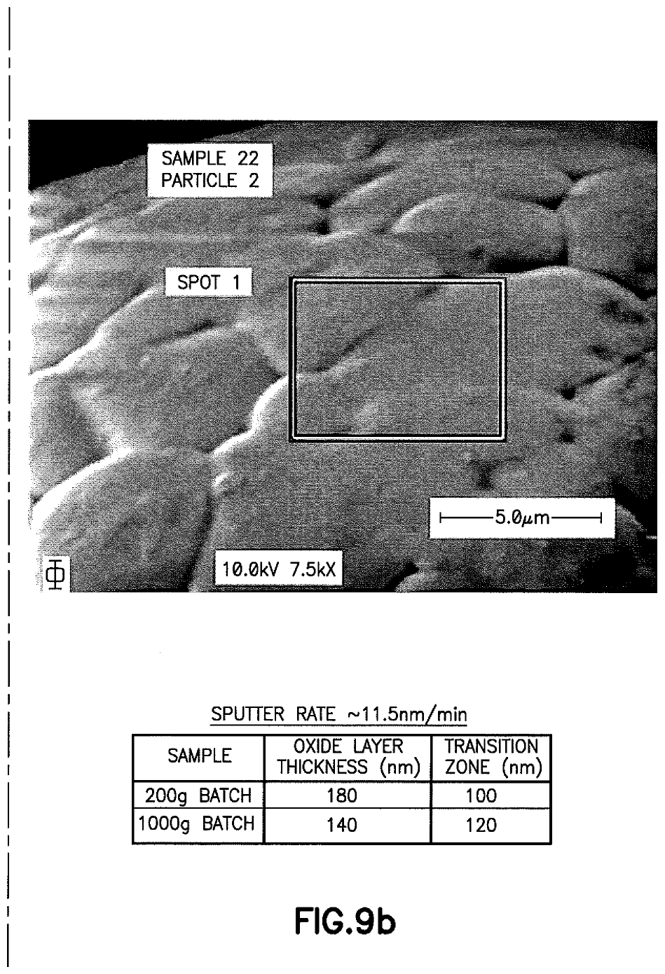

Referring to FIG. 9, auger electron spectroscopy analysis of individual powder particles having a core-shell morphology is shown generally at 1000. The analysis shows a variation of elemental concentration with respect to depth. The results on powder produced through the oxidation process confirm an absence of iron atoms and a presence of aluminum and oxygen atoms on the surface (shell).

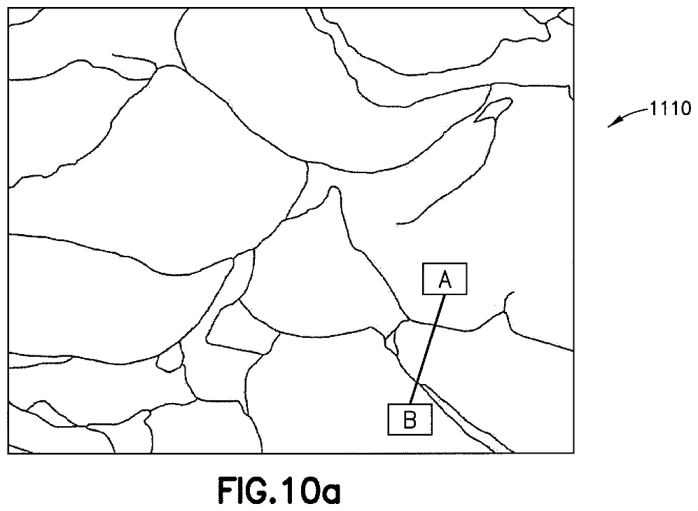

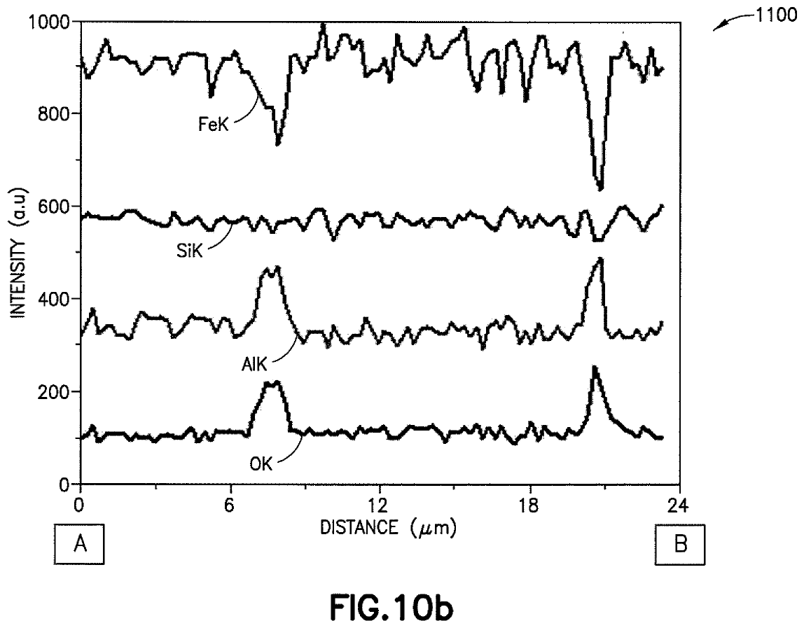

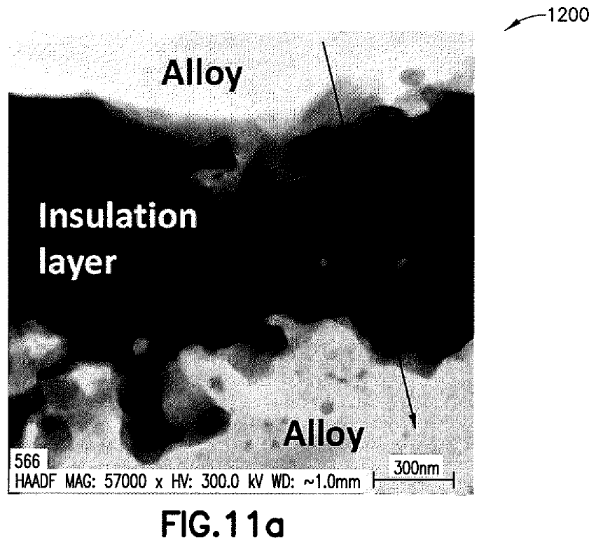

Referring to FIG. 10a, an SEM image of soft magnetic composite material produced by spray-forming the powder is shown generally at 1100, and referring to FIG. 10b, an accompanying energy dispersive spectroscopy (EDS) analysis of the spray formed material produced from powder with an oxide-based core-shell morphology is shown generally at 1110. These analyses 1100, 1110 also confirm the presence of exclusively aluminum and oxygen on the domain boundaries.

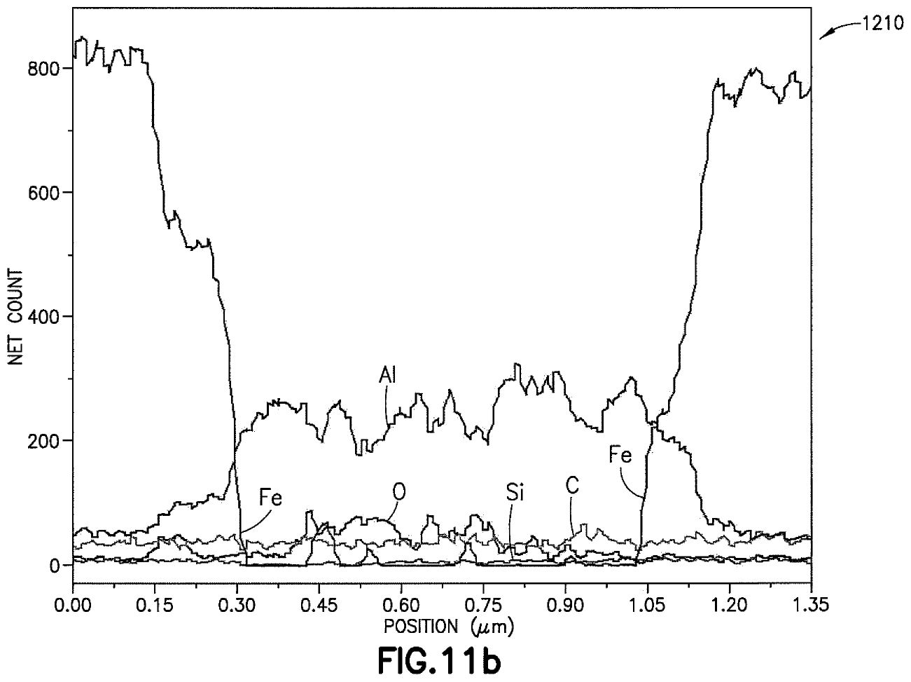

Referring to FIG. 11a, a transmission electron microscopy (TEM) image of alloy core insulation layer (of bulk material produced by spray-forming the powder) is shown generally at 1200, and referring to FIG. 11b, an accompanying EDS analysis is shown at 1210. The analysis 1210 illustrates particle boundary elemental concentration variation. The spray-forming process is characterized by high speed impact of particles on a surface. FIGS. 10a, 10b, 11a, and 11b show analysis results on soft magnetic composite material. In particular, these Figures illustrate that the insulating shells remain largely intact despite the impact during the spray-forming process and subsequent deposition. The core-shell structure is structurally sound to withstand such impact.

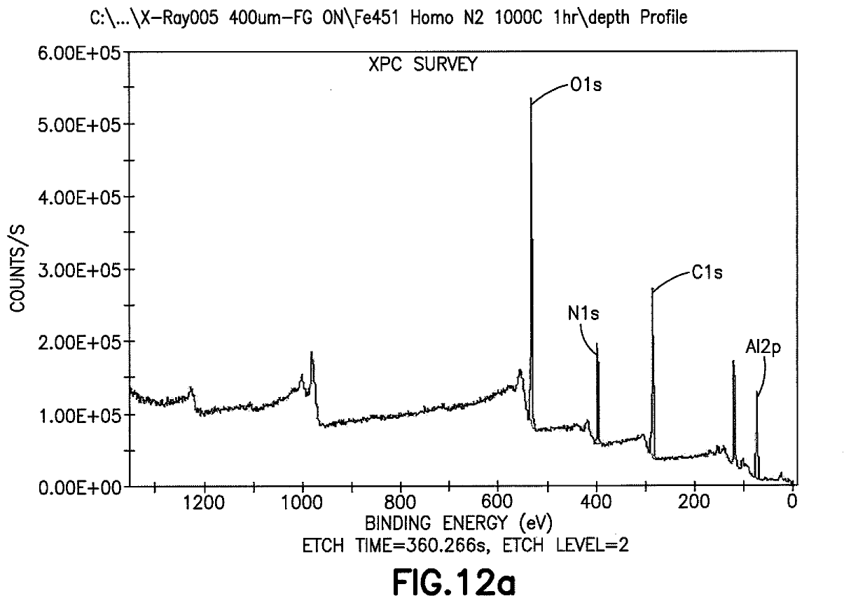

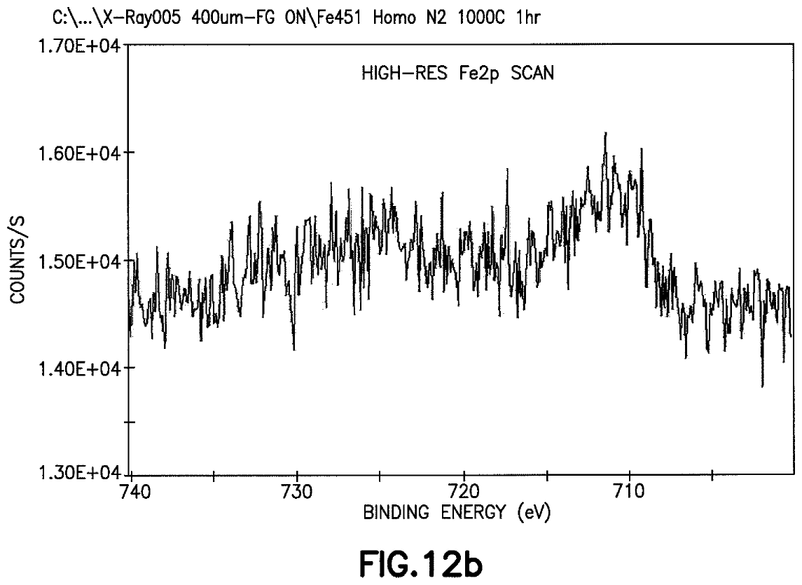

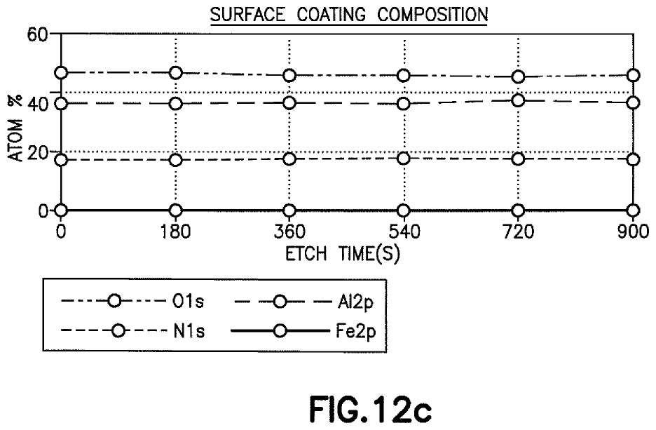

Referring to FIGS. 12a-12c, X-ray photoelectron spectroscopy (XPS) analysis of a powder surface showing an absence of a significant iron peak and the presence of an aluminum peak is shown at 1300. XPS survey spectra of the powder surface shows peaks corresponding to aluminum and shows no significant peaks corresponding to iron on the surface. In FIG. 12b, a high-resolution spectrum shows traces of iron in concentrations of less than about 1 atom percent. In addition, etching of the particles to expose regions immediately below the particle surface did not reveal any significant peaks corresponding to iron. FIG. 12c shows atom percent changes of oxygen, aluminum, nitrogen, and iron (in the is, 2p, 1s, and 2p orbitals, respectively) over time.

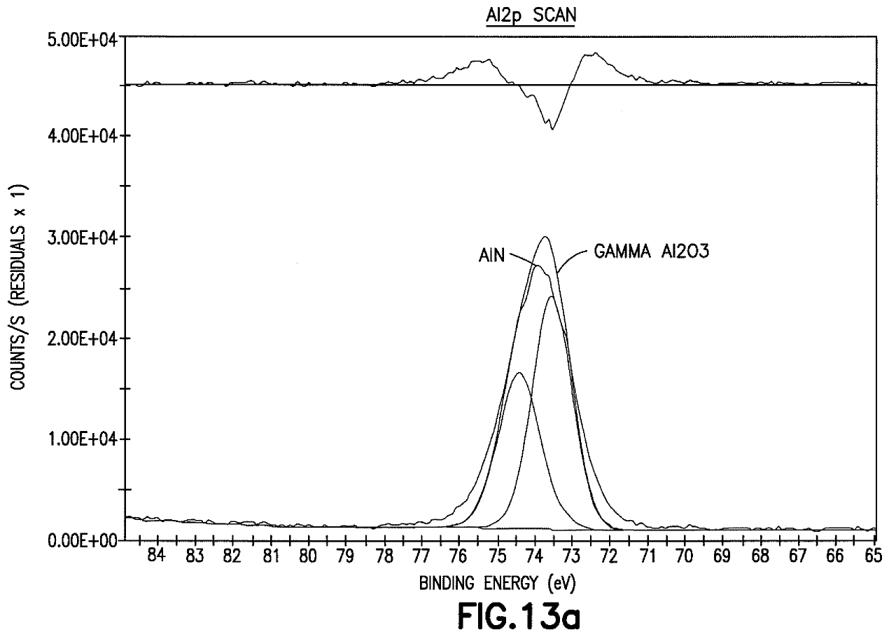

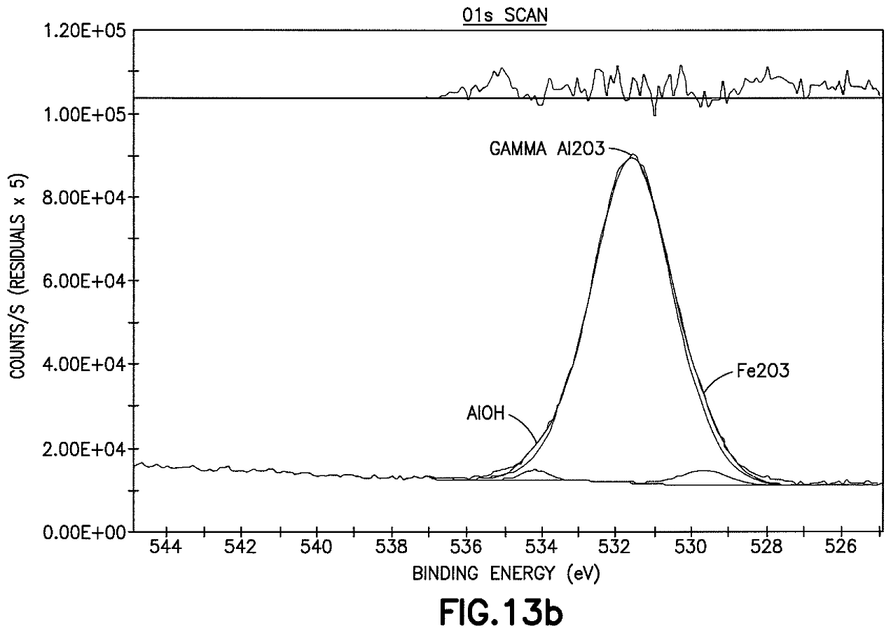

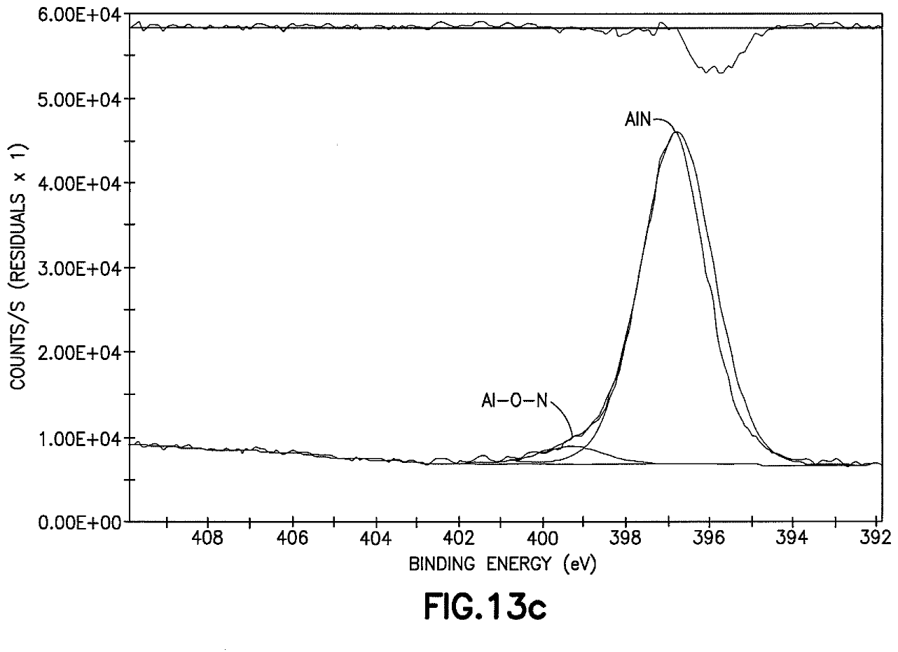

Referring to FIGS. 13a-13c, a high-resolution spectrum from XPS analysis in the vicinity of the aluminum, oxygen, and nitrogen binding energy reveals the presence of peaks corresponding to aluminum oxide in oxide based shells and aluminum-oxide-nitride in nitride based shells.

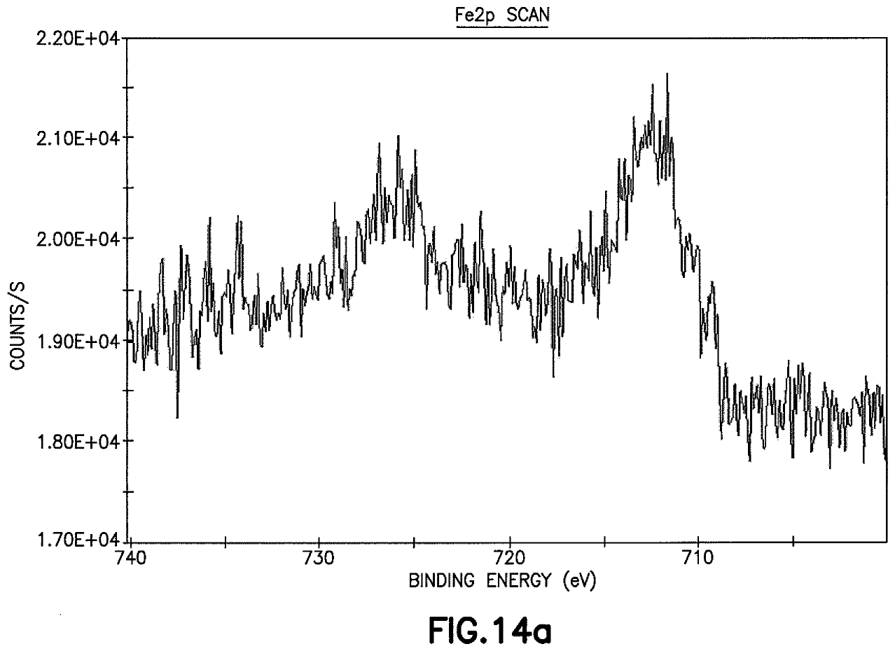

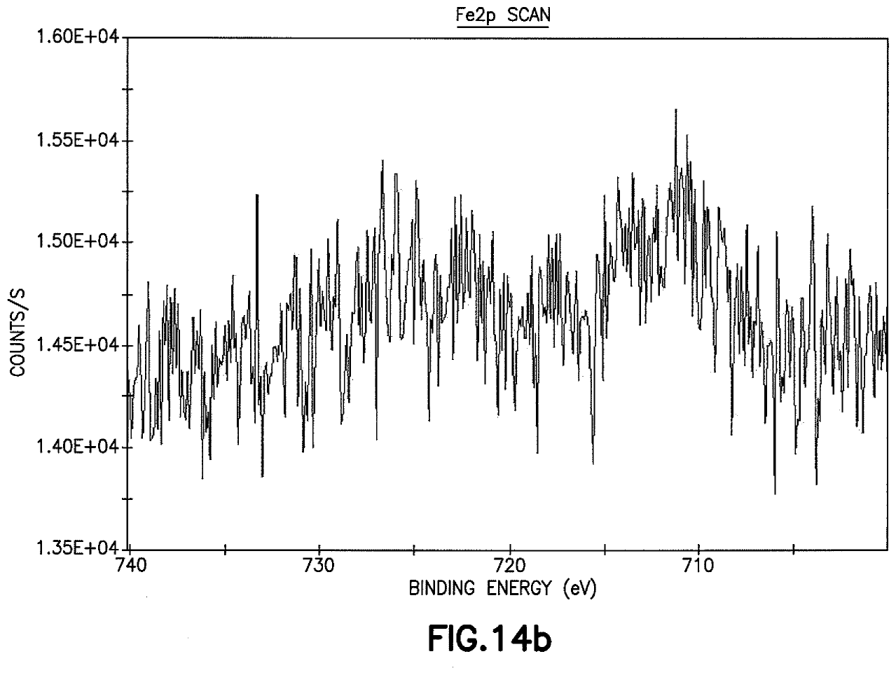

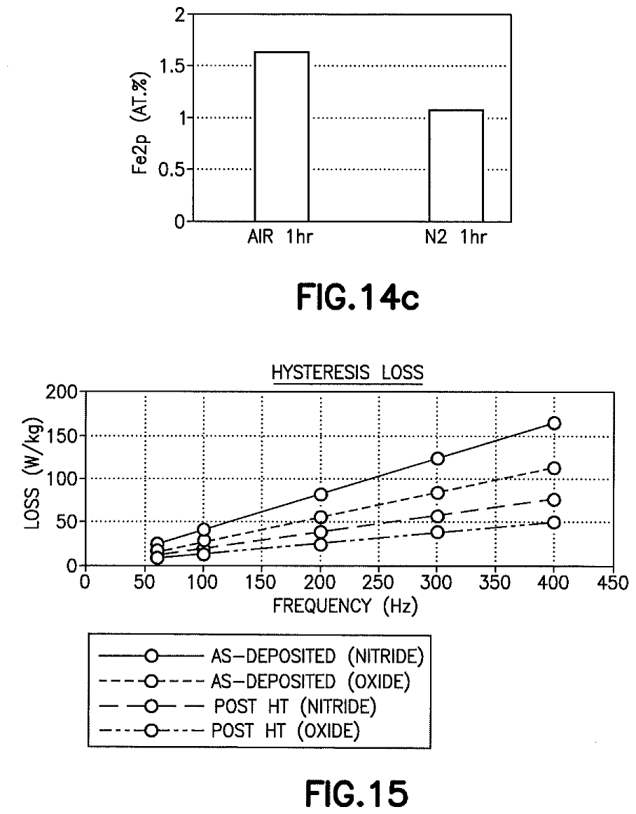

Referring now to FIGS. 14a-14c, XPS analysis of oxide and nitride shell powder surface (5 wt. % aluminum in core) is shown. A high intensity of iron peak from an oxide recipe powder displays the presence of iron in the shell. A low surface iron content (less than about 1 atom %) on particle boundaries and high saturation flux are both desirable properties in high performance soft-magnetic materials. FIGS. 14a-14c compare the surface iron content in powder produced through the two processes in an alloy with 5 wt. % aluminum in the core. The effectiveness of the oxide recipes may be limited to alloys containing 7 wt. % or greater aluminum content. On the other hand, nitride recipes are applicable to alloys with a wider range of aluminum content, for example, as low as 3.5 wt. %. FIGS. 14a-14c show a lower Fe content on the surface for the nitride based shell.

Described below are various advantages of producing bulk material using powder with nitride based shell over powder with oxide based shell. A nitride-based process enables production of core-shell powders with a lower aluminum content (3.5 wt. % compared to 7 wt. % in an oxide-based process, as shown in the first two columns of Table 1.1). Also, saturation flux of Fe—Al alloys is inversely proportional to the percentage of aluminum (as shown in Table 1.2). Therefore, a nitride-based process results in solid spray-formed materials with a higher saturation flux (compared to oxide-based processes), all other parameters being identical. Table 1.3 illustrates the correlation between aluminum content and measured saturation flux of the bulk material produced through the spray-forming process that is optimized to loss. Nitride based shells enable higher saturation flux levels compared to oxide based shells.

TABLE 1.1
Comparison of possible shell types for alloys
with varying aluminum concentrations
(numbers preceding element abbreviations
refer to weight percent).

| Core Composition | Shell type |
|---|---|
| Fe—7Al—3Si | Oxide/nitride |
| Fe—6Al—2.5Si | Nitride |
| Fe—5Al—2Si | Nitride |
| Fe—3.5Al—2Si | Nitride |

TABLE 1.2
Saturation flux of cast alloys as a
function of alloy content (numbers
preceding element abbreviations
refer to weight percent).

| | Saturation |
|---|---|
| Composition of | flux |
| cast alloy | (T) |
| Fe—9Al—1Si | 1.686 |
| Fe—7Al—1Si | 1.850 |
| Fe—5Al—1Si | 1.951 |

TABLE 1.3
Comparison of saturation flux and loss in bulk
material samples as a function of alloy
content (numbers preceding element
abbreviations refer to weight percent).

| | | Saturation |
|---|---|---|
| Composition of | | flux |
| core | Shell type | (T) |
| Fe—7Al—3Si | Oxide/nitride | 1.42 |
| Fe—6Al—2.5Si | Nitride | 1.52 |
| Fe—5Al—2Si | Nitride | 1.60 |
| Fe—3.5Al—2Si | Nitride | 1.70 |

Table 2 shows a comparison of thermal conductivity of samples of bulk material produced from oxide shell based powders and nitride shell based powders in a spray forming process. Aluminum nitride has a better thermal conductivity and hence the solid material produced from nitride based particles has better thermal conductivity than oxide based counterpart. As shown in Table 2, higher thermal conductivities may be experienced. Material produced from nitride based powders yields two to three times higher thermal conductivity over materials produced from oxide based powders.

TABLE 2
Comparison of thermal properties of bulk material
produced with oxide and nitride based powders.

| | Specific heat | Thermal | Thermal | |
|---|---|---|---|---|
| | Cₚ | diffusivity α | conductivity λ | CTE @ |
| Material | (J/g-K) | (mm²/s) | (W/m-K) | 150° C. |
| Oxide | 0.612 ± 0.011 | 0.912 ± 0.002 | 3.63 | 12.0E−6 |
| based | | | | |
| shell | | | | |
| Nitride | 0.556 ± 0.012 | 2.09 ± 0.004 | 7.23 | 12.3E−6 |
| based | | | | |
| shell | | | | |

Referring now to FIG. 15, the heat treatment of the spray-formed material (described herein) is shown. The heat treatment results in greater than 50% reduction in hysteresis loss for materials produced from both oxide based and nitride based powders.

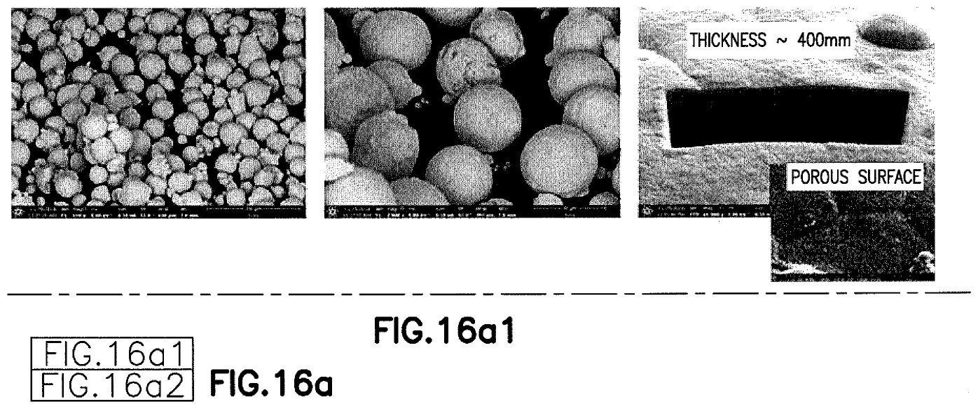

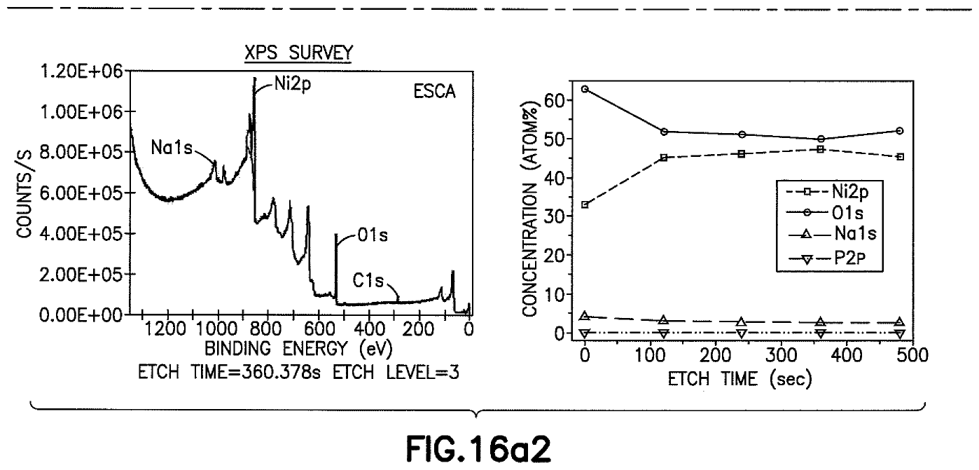

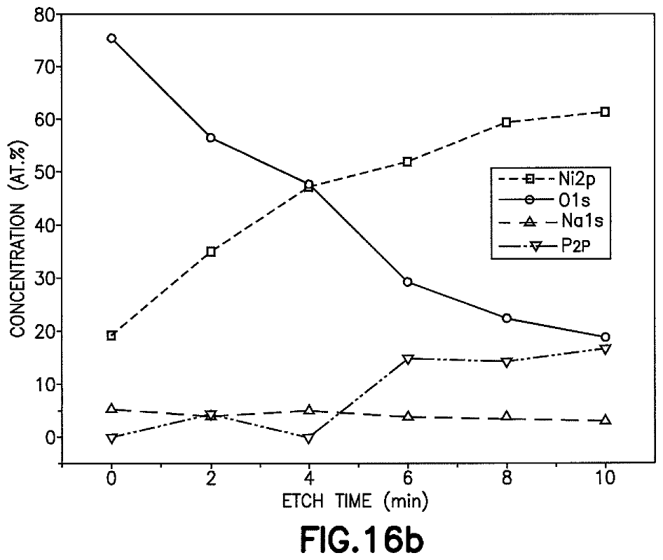

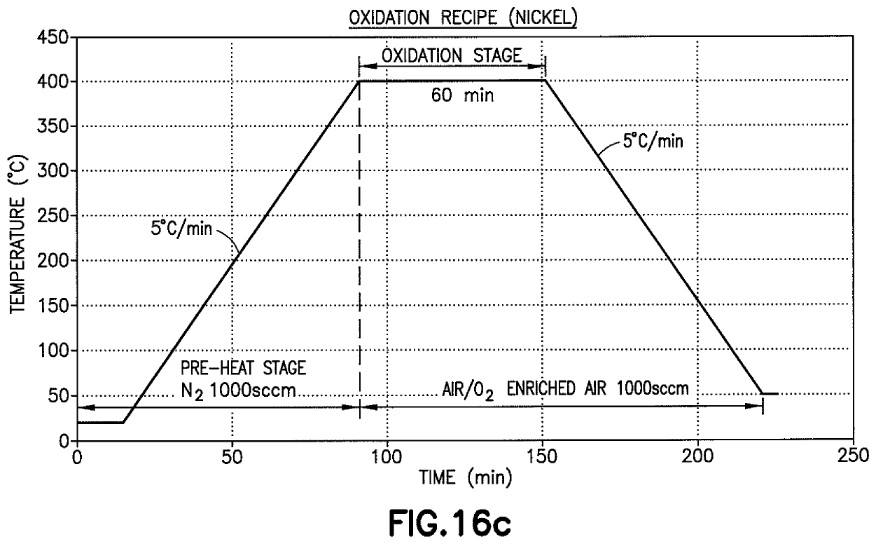

In some example embodiments, particles having core-shell structures may be formed in which the core is ferrous and the shell comprises nickel oxide. Referring to FIGS. 16a-16c, a metallic coating of nickel is deposited on magnetic core particles using an electroless deposition method. As with previous example embodiments, particle sizes of the cores range from 25 to 100 micrometers. The uniform (or substantially uniform) coverage of the magnetic core is clearly visible in FIG. 16a. The thickness of the deposited nickel coating is about 0.4 micrometers (400 nm) (for example, about 0.3 micrometers to about 0.5 micrometers). The coating chemistry is further confirmed from XPS studies showing an absence of surface iron as a function of etch time (FIG. 16a). The coated powder is heat treated in air to produce a shell comprised of nickel oxide as shown in FIG. 16b. No trace of iron or iron oxide is observed on the shell. This two-step process allows for the creation of a core-shell structure of powder without the need for an alloyed oxidizing or nitriding element in the magnetic core, for example aluminum. This method requires no aluminum in the core. Other methods such as atomic layer deposition (ALD), physical vapor deposition (PVD), chemical vapor deposition (CVD), thermal evaporation, electro pulse deposition (EPD), and the like can be used instead of electroless deposition to coat the particles with nickel. FIG. 16c shows the time-temperature plot of the heat treatment recipe to produce a nickel oxide based shell on particles with an iron based core.

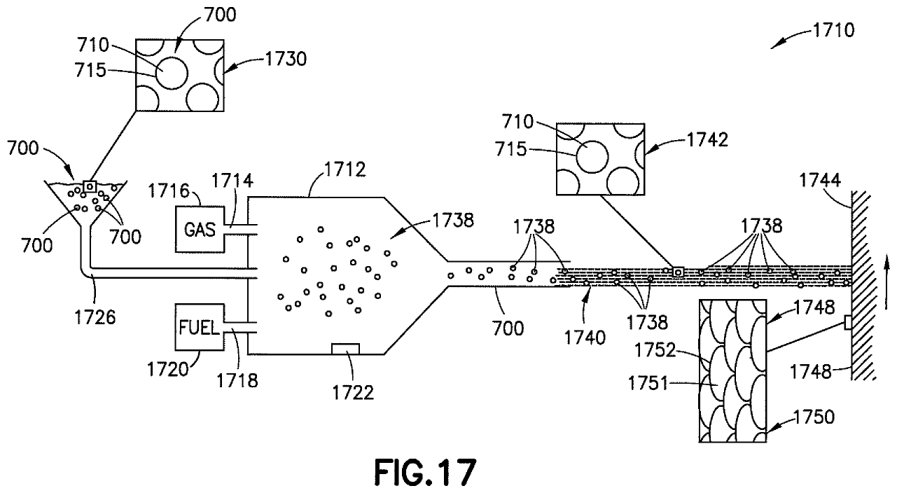

In another example embodiment, FIG. 17 illustrates a system 1710, and the method thereof, used to form (for example, spray-form) the material having domains with insulated boundaries by injecting a metal powder comprising particles of core-shell structures, for example, particles 700, into a chamber to partially melt the shells. The conditioned particles 700 are then directed at a stage to form the soft magnetic composite material having domains with insulated boundaries. System 1710 includes combustion chamber 1712 and gas inlet 1714 which injects gas 1716 into chamber 1712. Fuel inlet 1718 injects fuel 1720 into chamber 1712. Fuel 1720 may be a fuel such as kerosene, natural gas, butane, propane, and the like. Gas 1716 may be pure oxygen, an air mixture, or similar type gas. The result is a flammable mixture inside chamber 1712. Igniter 1722 is configured to ignite the flammable mixture of fuel and gas to create a predetermined temperature and pressure in combustion chamber 1712. Igniter 1722 may be a spark plug or similar type device. The resulting combustion increases the temperature and pressure within combustion chamber 1712, and the combustion products are propelled out of chamber 1712 via outlet 1724. Once the combustion process achieves a steady state (when the temperature and pressure in combustion chamber stabilizes), for example, to a temperature of about 1500K and a pressure of about 1 MPa, metal powder is injected into combustion chamber 1712 via inlet 1726. The metal powder is preferably comprised of the particles 700 (core-shell structures). As shown by caption 1730, particles 700 of metal powder include inner cores 710 made of a soft magnetic material, such as iron, silicon, and possibly aluminum, and outer shells 715 made of the crystalline phases of alumina, spinel, aluminum nitrides, and/or oxynitrides, which results in the shells 715 having a high melting temperature. The metal powder comprised of metal particles 700 having inner cores 710 with insulating shells 715 may be produced by the methods described herein.

After metal powder particles 700 are injected into combustion chamber 1712, particles 700 undergo softening and partial melting due to the high temperature in chamber 1712 to form conditioned droplets 1738 inside chamber 1712. Preferably, conditioned droplets 1738 have a soft and/or partially melted inner core 710 made of a soft magnetic material and a solid outer shell 715 made of the electrically insulated material. Conditioned droplets 1738 are then accelerated and ejected from outlet 1724 as stream 1740 that includes both combustion gases and conditioned droplets 1738. As shown in caption 1742, droplets 1738 in stream 1740 preferably have a completely solid outer shell 715 and a softened and/or partially melted inner core 710. Stream 1740, carrying conditioned droplets 1738, is directed at stage 1744. Stream 1740 is preferably traveling at a predetermined speed, for example, about 350 m/s. Conditioned droplets 1738 then impact stage 1744 and adhere thereto to form soft magnetic composite material 1748 having domains with insulated boundaries thereon. Caption 1750 shows in further detail one example of material 1748 with domains 1751 of soft magnetic material with electrically insulated boundaries 1752.

The processes and systems described herein may be extended to other alloying elements as well. Powder compositions involving iron alloyed with titanium or silicon can produce shells comprising the respective nitrides or oxynitrides. The processes and systems may also be used to produce powders with core-shell morphology for processes other than spray-forming to produce bulk soft magnetic material. Examples of such processes include various forms of sintering and mechanical compaction.

In one example, a system comprises a gas supply configured to supply at least one gas; and a furnace configured to receive the at least one gas. A flow of the at least one gas is configured to be varied to provide a shell on a particle in the furnace.

The gas supply may comprise one or more of a nitrogen source, an oxygen source, an air source, an inert gas, or vacuum. The furnace may comprise at least one heater configured to heat the particle. The system may further comprise a flow controller through which the at least one gas is fed to the furnace. The system may further comprise a pressure sensor downstream of the flow controller and upstream of the furnace. The system may further comprise a system controller, the system controller comprising at least one processor and at least one memory having software, the system controller being configured to adjust and control the supply of the at least one gas through the flow controller and being configured to control a temperature in the furnace. Adjustment and control of the supply of the at least one gas through the flow controller and control of the temperature of the furnace may be based on at least a pressure from the pressure sensor, the temperature in the furnace, or one or more of temperature or flow rate of the at least one gas. The system may further comprise a computer database in communication with the pressure sensor. The system may further comprise means to vary the flow of the at least one gas.

In another example, a method of providing a soft magnetic material having a core-shell structure comprises purging a furnace with nitrogen, inert gas, or vacuum; heating the furnace; determining if a shell on a ferrous particle is an oxide, a nitride, or an oxynitride; and oxidizing and/or nitriding the ferrous particle to form the shell.

Heating the furnace may comprise maintaining a temperature of the furnace below a temperature at which the nitrogen reacts with the ferrous particle. If the shell on the ferrous particle is determined to be the oxide, the method may further comprise switching a flow of the nitrogen/argon purging the furnace to a flow of air and oxidizing the ferrous particle. If the shell on the ferrous particle is determined to be the nitride, the method may further comprise maintaining a flow of the nitrogen/argon purging the furnace and increasing the temperature of the furnace to a temperature at which the nitrogen reacts with the ferrous particle. The method may further comprise cooling the oxidized or nitrided ferrous particle.

In another example, a soft magnetic material comprises a soft magnetic core; and a shell surrounding the soft magnetic core, the shell being chemically bonded to the core. The soft magnetic core comprises a soft magnetic elemental metal or alloy. The shell comprises an electrically insulating material.

The soft magnetic elemental metal or alloy may comprise one or more of iron, cobalt, nickel or gadolinium. The soft magnetic elemental metal or alloy may further comprise aluminum. The electrically insulating material may comprise one or more crystalline phases of oxides, nitrides, or oxynitrides. The shell may be uniform and substantially continuous around the soft magnetic core. The shell may be devoid of iron oxides.

In another example, a reactor comprises a cylindrical portion configured to be heated and comprising an inner wall and rotatable about an axis extending longitudinally through the cylindrical portion, the cylindrical portion having a first open end and a second opposing open end and having at least one vane extending from the inner wall; a first narrow portion attached to the first open end; and a second narrow portion attached to the second opposing open end.

The first narrow portion may comprise an inlet configured to receive a gas, and the second narrow portion may comprise an outlet configured to exhaust the gas. The cylindrical portion may comprise at least one of quartz, aluminum oxide, a nickel-based super alloy, or a cobalt-based super alloy.

In another example, a method of producing a soft magnetic composite material comprises providing a powder comprising at least one of iron, cobalt, nickel, aluminum, silicon, or gadolinium; forming shells on particles of the powder, the shells comprising an oxide, a nitride, or an oxynitride to form particles of a soft magnetic material having a core-shell structure; and forming a solid soft magnetic composite material using the particles of the soft magnetic material having the core-shell structure.

The method may further comprise heat treating the soft magnetic material. The heat treating may comprise heating to a specific temperature and maintaining the temperature for a predetermined time. The predetermined time may be 200 minutes to 800 minutes. The heat treating may be carried out under an inert atmosphere or vacuum. Forming the solid soft magnetic composite material using the particles of the soft magnetic material having the core-shell structure may comprise spray-forming the particles. Forming the solid soft magnetic composite material using the particles of the soft magnetic material having the core-shell structure may comprise a process selected from compaction, sintering, spark-plasma sintering, flash-sintering, hot-isostatic pressing, cladding, and laser cladding. Spray-forming the particles may comprise a process selected from one or more of high-velocity oxy-fuel (HVOF) processing, high-velocity air-fuel (HVAF) processing, hybrid HVOF-HVAF processes, atmospheric and vacuum plasma spray (APS/VPS), cold spray, and arc spray. The shells may remain intact during the forming of the solid soft magnetic composite material. The method may further comprise partially melting the shells prior to forming a solid soft magnetic composite material.

In another example, a method of producing a soft magnetic composite material comprises providing a powder comprising at least one of iron, cobalt, nickel, aluminum, silicon, or gadolinium; forming shells on particles of the powder, the shells comprising a nitride or an oxynitride to form particles of a soft magnetic material having a core-shell structure; and depositing the particles of the soft magnetic material having the core-shell structure to form a solid soft magnetic composite material.

The method may further comprise heat treating the particles of the soft magnetic material. The heat treating may comprise heating to a specific temperature and maintaining the temperature for a predetermined time. The predetermined time may be 200 minutes to 800 minutes. The heat treating may be carried out under an inert atmosphere or vacuum. Depositing the particles of the soft magnetic material may comprise spray-forming the particles. Spray-forming the particles may comprise a process selected from one or more of high-velocity oxy-fuel (HVOF) processing, high-velocity air-fuel (HVAF) processing, hybrid HVOF-HVAF processes, atmospheric and vacuum plasma spray (APS/VPS), cold spray, and arc spray. Depositing the particles of the soft magnetic material may comprise a process selected from compaction, sintering, spark-plasma sintering, flash-sintering, hot-isostatic pressing, cladding, and laser cladding. A content of aluminum may be less than 7 wt %. A saturation flux of the soft magnetic composite material may be at least 1.42 T.

In another example, a system for producing a soft magnetic powder material of particles having core-shell structures comprises a source of iron or iron alloy particles; a source of at least one gas comprising at least one of nitrogen and oxygen; a flow controller configured to control a flow of the at least one gas to the source of iron or iron alloy particles; and a heater configured to heat the at least one gas at the source of iron or iron alloy particles. A flow of the at least one gas is configured to be varied to provide a shell of at least one of a nitride, an oxide, or an oxynitride on the iron or iron alloy particles.

The system may further comprise a vacuum pump downstream of the heater. The system may further comprise a system controller having at least one processor and at least one memory, the controller being configured to control a flow of a supply of the at least one gas through the flow controller to the source of iron or iron alloy particles and/or a temperature of the heater. The system controller may operate by open-loop control or closed-loop control. The source of the at least one gas may comprise at least one of nitrogen and oxygen comprises at least one of diatomic nitrogen, diatomic oxygen, air, ozone, ozone-enriched air, hydrogen peroxide, ammonia, and hydrazine.

In another example, a soft magnetic material comprises a powder comprising particles of at least iron or iron alloy; and shells on the particles of the powder, the shells comprising nitride or an oxynitride to form particles of a soft magnetic material having a core-shell structure.

The soft magnetic material may further comprise particles of at least one of silicon, cobalt, nickel, aluminum, or gadolinium. The powder may further comprise silicon at 1 wt. %-3 wt. %, aluminum at less than 7.0 wt. %, and the balance may be iron. The shells may further comprise an oxide. The particles of powder may form cores of soft magnetic domains and the shells may form insulating boundaries over the soft magnetic domains. A soft magnetic composite material may be formed by the soft magnetic material.

In another example, a soft magnetic composite material comprises a plurality of particles of a soft magnetic material, the particles each having a core-shell structure. A core of each particle comprises a ferrous material that forms a ferromagnetic domain, and a shell on each core comprises a nitride material that forms an insulating boundary between adjacent cores.

The core of each particle may comprise less than 7.0 wt. % aluminum. The core of each particle may comprise 1.0 wt. %-3.0 wt. % silicon.

In another example, a soft magnetic material comprises a powder comprising particles of at least iron or iron alloy; and shells on the particles of the powder, the shells comprising nickel oxide to form particles of a soft magnetic material having a core-shell structure.

The shells may be devoid of iron and iron oxide. The particles may be about 25-100 micrometers in diameter and the shells may be about 0.05-0.5 micrometers in thickness. The shells may be deposited on the particles by electroless deposition.

In another example, a soft magnetic composite material comprises a plurality of particles of a ferrous soft magnetic material, the ferrous soft magnetic material forming ferromagnetic domains, and a shell on each core comprising nickel oxide, the shells forming insulating boundaries between adjacent ferromagnetic domains.

In another example, an apparatus comprises a combustion chamber having a gas inlet configured to receive a gas, a fuel inlet configured to receive a fuel, a particle inlet, and an outlet; and a stage configured to receive a stream of particles propelled from the outlet of the combustion chamber.

The combustion chamber may be configured to produce an ignitable flammable mixture of the gas and the fuel. The gas may be one or more of oxygen or air, and the fuel may be one or more of kerosene, natural gas, butane, or propane. The ignitable flammable mixture may be combustible to produce a temperature of 1500K at a pressure of 1 MPa in the combustion chamber.

It should be understood that the foregoing description is only illustrative. Various alternatives and modifications can be devised by those skilled in the art. For example, features recited herein could be combined with other features in any suitable combination(s). In addition, features from different embodiments described above could be selectively combined into a new embodiment. Accordingly, the description is intended to embrace all such alternatives, modifications, and variances.

What is claimed is:

1. A system for producing a soft magnetic material having a core-shell structure, the system, comprising:
a gas supply configured to supply at least one gas; and
a furnace configured to receive the at least one gas;
wherein a flow of the at least one gas is configured to be varied to provide a shell on a particle in the furnace.

2. The system of claim 1, wherein the gas supply comprises one or more of a nitrogen source, an oxygen source, an air source, an inert gas, or vacuum.

3. The system of claim 1, wherein the furnace comprises at least one heater configured to heat the particle.

4. The system of claim 1, further comprising a flow controller through which the at least one gas is fed to the furnace.

5. The system of claim 4, further comprising a pressure sensor downstream of the flow controller and upstream of the furnace.

6. The system of claim 5, further comprising a system controller, the system controller comprising at least one processor and at least one memory having software, the system controller being configured to adjust and control the supply of the at least one gas through the flow controller and being configured to control a temperature in the furnace.

7. The system of claim 6, wherein adjustment and control of the supply of the at least one gas through the flow controller and control of the temperature of the furnace is based on at least a pressure from the pressure sensor, the temperature in the furnace, or one or more of temperature or flow rate of the at least one gas.

8. The system of claim 1, wherein the gas supply is further configured to deliver at least one of argon, helium, and neon to the furnace to purge the furnace.

9. The system of claim 1, further comprising means to vary the flow of the at least one gas.

10. A method of providing a soft magnetic material having a core-shell structure, the method comprising:
purging a furnace with one or more of nitrogen, inert gas, or vacuum;
heating the furnace;
determining if a shell on a ferrous particle in the furnace is to be an oxide, a nitride, or an oxynitride; and
oxidizing and/or nitriding the ferrous particle to form the shell.

11. The method of claim 10, wherein heating the furnace comprises maintaining a temperature of the furnace below a temperature at which the nitrogen reacts with the ferrous particle.

12. The method of claim 11, wherein if the shell on the ferrous particle is determined to be the oxide, further comprising,
switching a flow of the nitrogen purging the furnace to a flow of air, and
oxidizing the ferrous particle.

13. The method of claim 11, wherein if the shell on the ferrous particle is determined to be the nitride, further comprising,
maintaining a flow of the nitrogen purging the furnace, and
increasing the temperature of the furnace to a temperature at which the nitrogen reacts with the ferrous particle.

14. The method of claim 10, further comprising cooling the oxidized or nitrided ferrous particle.

15. The method of claim 10, wherein a thickness of the shell is varied by varying a temperature and time in the furnace.

16. A soft magnetic material, comprising:
a soft magnetic core; and
a shell surrounding the soft magnetic core, the shell being chemically bonded to the core;
wherein the soft magnetic core comprises a soft magnetic elemental metal or alloy; and
wherein the shell comprises an electrically insulating material.

17. The soft magnetic material of claim 16, wherein the soft magnetic elemental metal or alloy comprises one or more of iron, cobalt, nickel, or gadolinium.

18. The soft magnetic material of claim 17, wherein the soft magnetic elemental metal or alloy further comprises aluminum.

19. The soft magnetic material of claim 16, wherein the electrically insulating material comprises one or more crystalline phases of oxides, nitrides, or oxynitrides.

20. The soft magnetic material of claim 16, wherein the shell is uniform and substantially continuous around the soft magnetic core.

21. The soft magnetic material of claim 16, wherein the shell is devoid of iron oxides.

22. A reactor, comprising:
a cylindrical portion configured to be heated and comprising an inner wall and rotatable about an axis extending longitudinally through the cylindrical portion, the cylindrical portion having a first open end and a second opposing open end and having at least one vane extending from the inner wall;
a first narrow portion attached to the first open end; and
a second narrow portion attached to the second opposing open end.

23. The reactor of claim 22, wherein the first narrow portion comprises an inlet configured to receive at least one gas, and wherein the second narrow portion comprises an outlet configured to exhaust the gases.

24. The reactor of claim 22, wherein the cylindrical portion comprises at least one of quartz, aluminum oxide, a nickel-based super alloy, or a Cobalt-based super alloy.

25. A method of producing a soft magnetic composite material, the method comprising:
providing a powder comprising at least one of iron, cobalt, nickel, aluminum, silicon, or gadolinium;
forming shells on particles of the powder, the shells comprising an oxide, a nitride, or an oxynitride to form particles of a soft magnetic material having a core-shell structure; and
forming a solid soft magnetic composite material using the particles of the soft magnetic material having the core-shell structure.

26. The method of claim 25, further comprising heat treating the soft magnetic material.

27. The method of claim 26, wherein the heat treating comprises heating to a specific temperature and maintaining the temperature for a predetermined time.

28. The method of claim 27, wherein the predetermined time is 200 minutes to 800 minutes.

29. The method of claim 27, wherein the heat treating is carried out under an inert atmosphere or vacuum.

30. The method of claim 25, wherein forming the solid soft magnetic composite material using the particles of the soft magnetic material having the core-shell structure comprises spray-forming the particles.

31. The method of claim 25, wherein forming the solid soft magnetic composite material using the particles of the soft magnetic material having the core-shell structure comprises a process selected from compaction, sintering, spark-plasma sintering, flash-sintering, hot-isostatic pressing, cladding, and laser cladding.

32. The method of claim 30, wherein spray-forming the particles comprises a process selected from one or more of high-velocity oxy-fuel (HVOF) processing, high-velocity air-fuel (HVAF) processing, hybrid HVOF-HVAF processes, atmospheric and vacuum plasma spray (APS/VPS), cold spray, and arc spray.

33. The method of claim 25, wherein the shells remain intact during the forming of the solid soft magnetic composite material.

34. The method of claim 25, further comprising partially melting the shells prior to forming a solid soft magnetic composite material.

35. A method of producing a soft magnetic composite material, the method comprising:
providing a powder comprising at least one of iron, cobalt, nickel, aluminum, silicon, or gadolinium;
forming shells on particles of the powder, the shells comprising a nitride or an oxynitride to form particles of a soft magnetic material having a core-shell structure; and
depositing the particles of the soft magnetic material having the core-shell structure to form a solid soft magnetic composite material.

36. The method of claim 35, further comprising heat treating the particles of the soft magnetic material.

37. The method of claim 36, wherein the heat treating comprises heating to a specific temperature and maintaining the temperature for a predetermined time.

38. The method of claim 37, wherein the predetermined time is 200 minutes to 800 minutes.

39. The method of claim 37, wherein the heat treating is carried out under an inert atmosphere or vacuum.

40. The method of claim 35, wherein depositing the particles of the soft magnetic material comprises spray-forming the particles.

41. The method of claim 40, wherein spray-forming the particles comprises a process selected from one or more of high-velocity oxy-fuel (HVOF) processing, high-velocity air-fuel (HVAF) processing, hybrid HVOF-HVAF processes, atmospheric and vacuum plasma spray (APS/VPS), cold spray, and arc spray.

42. The method of claim 35, wherein depositing the particles of the soft magnetic material comprises a process selected from compaction, sintering, spark-plasma sintering, flash-sintering, hot-isostatic pressing, cladding, and laser cladding.

43. The method of claim 35, wherein a content of aluminum is less than 7 wt %.

44. The method of claim 35, wherein a saturation flux of the soft magnetic composite material is at least 1.42 T.

45. A system for producing a soft magnetic powder material of particles having core-shell structures, the system comprising:
a source of iron or iron alloy particles;
a source of at least one gas comprising at least one of nitrogen and oxygen;
a flow controller configured to control a flow of the at least one gas to the source of iron or iron alloy particles; and
a heater configured to heat the at least one gas at the source of iron or iron alloy particles;
wherein a flow of the at least one gas is configured to be varied to provide a shell of at least one of a nitride, an oxide, or an oxynitride on the iron or iron alloy particles.

46. The system of claim 45, further comprising a vacuum pump downstream of the heater.

47. The system of claim 45, further comprising a system controller having at least one processor and at least one memory, the controller being configured to control a flow of a supply of the at least one gas through the flow controller to the source of iron or iron alloy particles and/or a temperature of the heater.

48. The system of claim 47, wherein the system controller operates by open-loop control or closed-loop control.

49. The system of claim 45, wherein the source of the at least one gas comprising at least one of nitrogen and oxygen comprises at least one of diatomic nitrogen, diatomic oxygen, air, ozone, ozone-enriched air, hydrogen peroxide, ammonia, and hydrazine.

50. A soft magnetic material, comprising:
a powder comprising particles of at least iron or iron alloy; and
shells on the particles of the powder, the shells comprising nitride or an oxynitride to form particles of a soft magnetic material having a core-shell structure.

51. The soft magnetic material of claim 50, wherein the powder further comprises particles of at least one of silicon, cobalt, nickel, aluminum, or gadolinium.

52. The soft magnetic material of claim 50, wherein the powder further comprises silicon at 1 wt. %-3 wt. %, aluminum at less than 7.0 wt. %, and the balance is iron.

53. The soft magnetic material of claim 50, wherein the shells further comprise an oxide.

54. The soft magnetic material of claim 50, wherein the particles of powder form cores of soft magnetic domains and the shells form insulating boundaries over the soft magnetic domains.

55. A soft magnetic composite material formed by the soft magnetic material of claim 54.

56. A soft magnetic composite material, comprising:
a plurality of particles of a soft magnetic material, the particles each having a core-shell structure, wherein a core of each particle comprises a ferrous material that forms a ferromagnetic domain, and wherein a shell on each core comprises a nitride material that forms an insulating boundary between adjacent cores.

57. The soft magnetic composite material of claim 56, wherein the core of each particle comprises less than 7.0 wt. % aluminum.

58. The soft magnetic composite material of claim 56, wherein the core of each particle comprises 1.0 wt. %-3.0 wt. % silicon.

59. A soft magnetic material, comprising:
a powder comprising particles of at least iron or iron alloy; and
shells on the particles of the powder, the shells comprising nickel oxide to form particles of a soft magnetic material having a core-shell structure.

60. The soft magnetic material of claim 59, wherein the shells are devoid of iron and iron oxide.

61. The soft magnetic material of claim 59, wherein the particles are about 25-100 micrometers in diameter and the shells are about 0.05-0.5 micrometers in thickness.

62. The soft magnetic material of claim 59, wherein the shells are deposited on the particles by electroless deposition.

63. A soft magnetic composite material, comprising:
a plurality of particles of a ferrous soft magnetic material, the ferrous soft magnetic material forming ferromagnetic domains defining cores, and a shell on each core comprising nickel oxide, the shells forming insulating boundaries between adjacent ferromagnetic domains.

64. An apparatus, comprising:
a combustion chamber having a gas inlet configured to receive a gas, a fuel inlet configured to receive a fuel, a particle inlet, and an outlet; and
a stage configured to receive a stream of particles propelled from the outlet of the combustion chamber.

65. The apparatus of claim 64, wherein the combustion chamber is configured to produce an ignitable flammable mixture of the gas and the fuel.

66. The apparatus of claim 65, wherein the gas is one or more of oxygen or air, and wherein the fuel is one or more of kerosene, natural gas, butane, or propane.

67. The apparatus of claim 65, wherein the ignitable flammable mixture is combustible to produce a temperature of 1500K at a pressure of 1 MPa in the combustion chamber.
